(19) United States
(12) Patent Application Publication
(10) Pub. No.: US 2023/0030586 A1
(43) Pub. Date: Feb. 2, 2023

(54) INTEGRATED CIRCUIT WITH TOPOLOGICAL SEMIMETAL INTERCONNECTS

(71) Applicant: YALE UNIVERSITY, New Haven, CT (US)

(72) Inventors: HyeukJin Han, New Haven, CT (US); Jeeyoung Cha, Woodbridge, CT (US)

(21) Appl. No.: 17/813,395

(22) Filed: Jul. 19, 2022

Related U.S. Application Data
(60) Provisional application No. 63/223,728, filed on Jul. 20, 2021.

(51) Int. Cl. H01L 23/532; H01L 23/528; C23C 16/30; C30B 25/02; C30B 29/14

(52) U.S. Cl. CPC H01L 23/53204; H01L 23/5283; C23C 16/30; C30B 25/02; C30B 29/14

(57) ABSTRACT

An integrated circuit comprises a first circuit element operably connected to a second circuit element by a nanowire interconnect; wherein the nanowire interconnect comprises molybdenum phosphide (MoP), tungsten phosphide (WP₂), or niobium phosphide (NbP). A nanowire interconnect can be made by providing a template nanowire; providing a phosphine source; producing phosphine from the phosphine source; and contacting the template nanowire with the phosphine. The nanowire interconnect demonstrates low resistance.

### CROSS-REFERENCE TO RELATED APPLICATIONS

The present application claims priority to U.S. Provisional Application No. 63/223,728, filed Jul. 20, 2021, which is incorporated by reference herein in its entirety.

### BACKGROUND

Interconnects are metal wires that connect transistors, transmit signals in computer chips, and occupy a large fraction of integrated circuits. In the early 2000s, copper (Cu) replaced aluminum as low-resistance interconnects for continued downscaling of integrated circuits (Science (80). 314, 1842-1843 (2006); P. Kapur, et al. IEEE Trans. Electron Devices. 49, 598-604 (2002)). However, Cu can no longer support the dimensional reduction at the smallest feature size of interconnects due to its ever-increasing resistivity that stems from surface and grain boundary electron scattering (M. H. Van Der Veen, et al. 2018 IEEE Int. Interconnect Technol. Conf. IITC 2018, 172-174 (2018)). The high resistivity of current Cu interconnects can account for up to 35% of total signal delays and nearly half of dynamic power dissipation in computer chips (A. Ceyhan, et al. IEEE Trans. Electron Devices. 62, 940-946 (2015)). Thus, future energy-efficient computing technologies require breakthroughs in interconnect technologies (S. Manipatruni, et al. Nature. 565, 35-42 (2019)), particularly in new interconnect materials.

Topological semimetals are promising materials for low resistance interconnects as their topologically protected surface electrons are forbidden to backscatter (A. A. Soluyanov, et al. Nature. 527, 495-498 (2015); P. Liu, et al. Nat. Rev. Mater. 4, 479-496 (2019); D. Gall, et al. MRS Bull. 46, 1-8 (2021)). Several experimental studies on nanostructured topological semimetals show promising results. The Weyl semimetal NbAs, for example, exhibits a factor of ten decrease in resistivity from bulk crystals (35 μΩ-cm) to nanobelts (˜3 μΩ-cm) at room temperature (C. Zhang, et al. Nat. Mater. 18, 482-488 (2019)). Similarly, recent theoretical results from IBM predict that the multifold fermion system CoSi would exhibit lower resistivity than Cu at very small dimensions as the current conduction is dominated by Fermi-arc surface states (C.-T. Chen, et al. in 2020 IEEE International Electron Devices Meeting (IEDM) (IEEE, 2020; https://ieeexplore.ieee.org/document/9371996/), vols. 2020-December, pp. 32.4.1-32.4.4).

There is need in the art for low resistance interconnects. The present invention satisfies this need.

### SUMMARY OF THE INVENTION

In one aspect, the present invention relates to an integrated circuit comprising a first circuit element operably connected to a second circuit element by a nanowire interconnect; wherein the nanowire interconnect comprises molybdenum phosphide (MoP), tungsten phosphide (WP₂), or niobium phosphide (NbP). The invention also relates to microchips comprising the integrated circuit. In one embodiment, the nanowire interconnect comprises MoP. In one embodiment, the nanowire interconnect does not include a liner. In one embodiment, the nanowire interconnect is polycrystalline and non-porous.

In one embodiment, the nanowire interconnect comprises fewer than 30 grain boundaries per micrometer length. In one embodiment, the nanowire interconnect has an average crystal grain size of 20 to 50 nm. In one embodiment, the nanowire interconnect has a diameter less than 100 nm. In one embodiment, the nanowire interconnect has a diameter less than 50 nm. In one embodiment, the nanowire interconnect has a diameter less than 20 nm. In one embodiment, the nanowire interconnect has a resistivity of 30 μΩ·cm to 10 μΩ·cm at room temperature. In one embodiment, the nanowire interconnect is a MoP nanowire and has a resistivity less than or equal to 10 μΩ·cm at room temperature. In one embodiment, the resistivity of the nanowire interconnect does not increase upon exposure to ambient conditions for 48 hours.

In one aspect, the present invention relates to a method of making a topological semimetal nanowire comprising the steps of: providing a template nanowire; providing a phosphine source; producing phosphine from the phosphine source; and contacting the template nanowire with the phosphine.

In one embodiment, template nanowire comprises molybdenum oxide, tungsten oxide, or niobium oxide. In one embodiment, the template nanowire comprises MoO₃. In one embodiment, the template nanowire has a diameter of less than 50 nm. In one embodiment, the template nanowire has a diameter of about 10 nm.

In one embodiment, the phosphine source comprises red phosphorous or a hypophosphite salt selected from the group consisting of sodium hypophosphite, potassium hypophosphite, lithium hypophosphite, rubidium hypophosphite, cesium hypophosphite, ammonium hypophosphite and mixtures and solvates thereof.

In one embodiment, the step of producing phosphine from the phosphine source comprises the steps of heating the phosphine source to a temperature greater than 300° C.; and contacting the phosphine source with hydrogen gas.

### BRIEF DESCRIPTION OF THE DRAWINGS

The following detailed description of preferred embodiments of the invention will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 is a graph showing the relationship between cross section area and line resistance for effective copper (copper with a barrier layer), ruthenium and MoP.

FIG. 2 shows a tube furnace useful for making MoP nanostructures.

FIG. 3 shows the x-ray diffraction (XRD) pattern of the MoO₃ and MoP nanostructures before and after the conversion reaction.

FIG. 4 is a graph showing the resistivity ratio vs. temperature for several polycrystalline MoP nanowires.

FIG. 5 is a graph of resistivity values of polycrystalline MoP nanowires having different cross-sectional areas and nanowires of effective copper (copper with a barrier layer), cobalt and ruthenium having different cross-sectional areas at room temperature.

FIG. 6A shows transmission electron micrographs of polycrystalline MoP nanowires.

FIG. 6B is a drawing of crystallite arrangement in polycrystalline MoP nanowires.

FIG. 7 is a graph showing the relationship between grain size, the number of grain boundaries and the diameter of the nanowire.

FIG. 8 is a graph showing the change in resistance of MoP nanowires and copper film when exposed to air.

FIG. 9 shows a tube furnace useful for making single crystal MoP nanowires.

FIG. 10 shows a molybdenum/liquid metal system for making single crystal MoP nanowires.

FIG. 11 is a phase diagram of the conversion of MoO₃ to MoP described below.

FIG. 12 is a schematic of the hexagonal crystal structure of MoP.

FIG. 13 is a depiction of calculated electronic band structures along high-symmetry k-point paths.

FIG. 14 depicts the Fermi surface of MoP with calculated electron mean free path lengths. The polyhedron represents the Brillouin zone.

FIG. 15 is a plot of the calculated resistivity scaling of MoP and Cu wires. Experimentally measured bulk resistivities r₀ (r when width→∞) for Cu and MoP are used. The curves for Cu correspond to p=0.

FIG. 16 depicts TEM images of MoP nanowires of varying diameters. Scale bars, 20 nm.

FIG. 17 is an atomic-resolution STEM image of a MoP nanowire showing high crystalline quality in single grains observed along the [010] direction, with bright Mo atomic columns. Scale bar, 1 nm. At inset is an atomic structure model of MoP viewed along the [010]direction (Blue: Mo atoms, White: P atoms).

FIG. 18A depicts an X-ray diffraction (XRD) analysis of MoP nanowires. All the diffraction peaks from the 2 theta XRD scan are clearly indexed to the MoP structure (JCPDS file: 65-6024).

FIG. 18B is a [111] zone-axis high-resolution TEM image of a MoP nanowire showing high crystalline quality in single grains. Scale bar, 5 nm.

FIG. 18C is a corresponding SAED pattern taken from nanowires shown in FIG. 16.

FIG. 19A is a TEM-EDS spectra acquired from a MoP nanowire and reference MoP bulk crystal.

FIG. 19B is a Raman spectra acquired from MoP nanowires and reference MoP bulk; one phonon mode is identified. a.u., arbitrary units.

FIG. 20 is a plot of I-V curves of polycrystalline MoP nanowires with decreasing diameter. At inset is a SEM image of a 33 nm-diameter MoP nanowire device.

FIG. 21 is a plot of the room temperature resistivity data of MoP nanowires with varying diameter (cross-sectional area).

FIG. 22 depicts schematics of MoP nanowires with diameter >45 nm (left) and <45 nm (right), respectively. For MoP nanowires with large diameters, grain boundaries that are parallel to current flow are present, increasing the resistivity. The horizontal arrows denote 45 nm.

FIG. 23 depicts temperature-resistivity (ρ) curves of MoP nanowires with varying diameter. At inset is a plot of residual resistance ratio (RRR) versus nanowire diameter.

FIG. 24 is a plot of the number of grain boundaries per unit length present as a function of the diameter of MoP nanowires.

FIG. 25 shows two MoP nanowire devices with different diameters, Scale bars, 50 nm.

FIG. 26 shows, at right, temperature-resistivity (ρ) curves of the two MoP nanowires with distinct microstructure differences; and at left, a comparison of the temperature dependence of the resistivity in these two nanowires. The RRR value of the nanowire shown at right in FIG. 25 is ˜2.22, whereas it is ˜6.25 for the wire shown at left.

FIG. 27 is a plot of the experimental resistivity data of MoP nanowires (blue square) and Cu wires (dotted line) below 7 nm BEOL nodes.

FIG. 28 is a plot of electrical resistivity as a function of wire width of polycrystalline square wires of Cu and MoP plotted using the Fuchs-Sondhemier and Mayadas-Shatzkes equation. The square data points are the experimentally measured resistivity of MoP in this work.

FIG. 29 is a comparison of the temperature coefficient of resistivity (TCR) values for MoP nanowires, Cu and Ru films.

FIG. 30 is a plot of line resistance of the Ru, Cu and MoP nanowires as a function of diameter (cross-section area).

FIG. 31 is, at left, a schematic of time-domain thermoreflectance (TDTR) measurements on the MoP nanoplate coated with an Al transducer layer; and at right, a typical fitting result of ratio (−Vᵢₙ/Vₒᵤₜ) signals as function of pump-probe delay time for thermal conductivity of MoP nanoplate. At inset is a SEM image of a MoP nanoplate. Scale bar, 5 μm.

FIG. 32 is, at left, a schematic of TDTR measurements on the MoP bulk crystal; and at right, a plot of fitting result of ratio signals for thermal conductivity of MoP bulk. The black dots are experimental data and the red line is the fitting line. The thermal conductivity of the MoP nanoplate is 99 W/m-K and the thermal conductivity of MoP bulk is 96 W/m-K.

FIG. 33 depicts an X-ray photoelectron spectroscopy (XPS) P 2p spectrum of MoP nanowires after annealing at various temperatures (as indicated) in air for 15 min. The P 2p region was deconvolved into three peaks at 129.2, 130.3, and 133.7 eV. The main pair of doublet peaks at 129.3 eV (P 2p3/2) and 130.2 eV (P 2p1/2) is assigned to P bonded to Mo atoms, while the peak at a higher binding energy of ˜133.7 eV is ascribed to oxidized P species, which grow rapidly at annealing temperatures >200° C. In situ Ar etching of MoP nanowires greatly suppresses the oxidized P peak, confirming that the natural oxidation is limited to the surface of the wires.

FIG. 34 is a plot of resistance measurements for three MoP nanowire devices (diameters of 37 nm, 43 nm, and 58 nm) over 48 hrs in ambient condition. The resistance values are stable over this period, indicating that MoP nanowires are resistant to surface oxidation.

FIG. 35 depicts a comparison of resistance change of MoP nanowire with 20 nm-thick Cu film as control.

FIG. 36 is a comparison chart of carrier density and resistivity of topological semimetals from literature.

FIG. 37 depicts the bandstructure of a 6.5 nm thick MoP (1000) slab, colored by contribution of spatial regions to each state: bulk in gray, Mo-terminated surface in blue and P-terminated surface in red.

FIG. 38 depicts the surface-projected Fermi surfaces for Mo-termination (left) and P-termination (right).

FIG. 39 is a plot of the normalized resistance-area (RA) product of Cu (100), CoSi (100) and MoP (1000) pristine films as a function of film thickness.

FIG. 40 is a depiction of the two-terminal NEGF setup used for the prediction of transmission for defect-laden films of MoP.

FIG. 41 is a plot of the k-resolved transmission for the different defect configurations obtained using NEGF in QuantumATK.

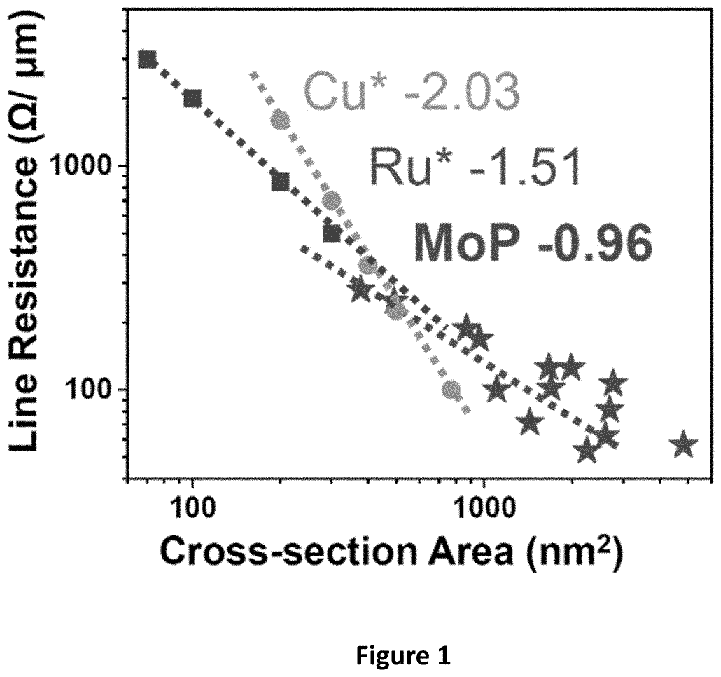

### DETAILED DESCRIPTION

It is to be understood that the figures and descriptions of the present invention have been simplified to illustrate elements that are relevant for a clear understanding of the present invention. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

As used herein, each of the following terms has the meaning associated with it in this section. Unless defined otherwise, all technical and scientific terms used herein generally have the same meaning as commonly understood by one of ordinary skill in the art to which this invention belongs.

The articles “a” and “an” are used herein to refer to one or to more than one (i.e. to at least one) of the grammatical object of the article. By way of example, “an element” means one element or more than one element.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

As used herein, “comprises” is explicitly intended to include both “consisting essentially of” and “consisting of”.

### Nanowire Interconnects

In one aspect, the present invention relates an integrated circuit comprising a first circuit element operably connected to a second circuit element by a nanowire interconnect; wherein the nanowire comprises a topological semimetal selected from the group consisting of molybdenum phosphide (MoP), tungsten phosphide (WP₂), and niobium phosphide (NbP). In one embodiment, interconnects are materials, typically wires, which operably connect circuit elements in an integrated circuit.

Materials are conventionally divided into metals, semiconductors, and insulators. Recently, through the lens of topology, materials can be reclassified as either topologically trivial or topologically non-trivial. Topologically non-trivial semimetals and metals exhibit novel, low-energy fermionic excitations. Exemplary topological semimetals include molybdenum phosphide (MoP), tungsten phosphide (WP₂) and niobium phosphide (NbP). Molybdenum phosphide (MoP) is a simple binary compound, which was first predicted and then confirmed experimentally to host topologically protected triple point (three-fold degenerate) fermions.

Molybdenum phosphide (MoP) has shown extremely low residual resistivity, high carrier density, high mobility, and long mean free path. The reported transport properties may have a transformative impact in the semiconductor industry as a potential solution to current challenges with Cu interconnects. The topological protection predicted for MoP may suppress the surface and grain-boundary electron scattering that plagues current Cu interconnects as they continue to shrink in size. Similar predictions may be made for WP₂ and NbP.

There is no particular limit to the composition of the integrated circuit. In one embodiment, the integrated circuit is part of a microchip or any other device employing an integrated circuit. Similarly, there is no particular limit to the circuit elements considered in this aspect.

In one embodiment, the nanowire has a diameter less than 100 nm. In one embodiment, the nanowire has a diameter less than 90 nm. In one embodiment, the nanowire has a diameter less than 80 nm. In one embodiment, the nanowire has a diameter less than 70 nm. In one embodiment, the nanowire has a diameter less than 60 nm. In one embodiment, the nanowire has a diameter less than 50 nm. In one embodiment, the nanowire has a diameter less than 40 nm. In one embodiment, the nanowire has a diameter less than 30 nm. In one embodiment, the nanowire has a diameter less than 20 nm. In one embodiment, the nanowire has a diameter less than 10 nm.

In one embodiment, the nanowire has a diameter between 10 nm and 100 nm. In one embodiment, the nanowire has a diameter between 10 nm and 90 nm. In one embodiment, the nanowire has a diameter between 10 nm and 80 nm. In one embodiment, the nanowire has a diameter between 10 nm and 70 nm. In one embodiment, the nanowire has a diameter between 10 nm and 50 nm. In one embodiment, the nanowire has a diameter between 10 nm and 40 nm. In one embodiment, the nanowire has a diameter between 10 nm and 30 nm. In one embodiment, the nanowire has a diameter between 10 nm and 20 nm.

In one embodiment, the nanowire has a diameter of about 50 nm, about 45 nm, about 40 nm, about 35 nm, about 30 nm, about 25 nm, about 20 nm, about 15 nm, or about 10 nm. In some embodiments of the invention, nanowires having smaller diameters also have lower resistivity. While not wishing to be bound to any one scientific theory, it is possible that nanowires having smaller diameters also comprise fewer grain boundaries parallel to the flow of current.

In one embodiment, the nanowire is non-porous. In one embodiment, the nanowire is a single crystal nanowire. In one embodiment, the nanowire is a polycrystalline nanowire.

In one embodiment, the polycrystalline nanowire comprises a plurality of crystal grains. In one embodiment, the average crystal grain size of the nanowires may be 10 to 50 nm, or 15 to 45 nm. In one embodiment, The number of grain boundaries per micrometer may vary with the diameter of the polycrystalline nanowire. For example, nanowires having a diameter of 60 to 100 nm may have greater than or equal to 45 grain boundaries per micrometer. Nanowire having a diameter of 10 to 45 nm may have less than 30 grain boundaries per micrometer. In one embodiment, an increased number of grain boundaries may result in more diverse resistivity values.

In one embodiment, a nanowire comprising MoP comprises molybdenum and phosphorous in an approximately 1:1 ratio. In one embodiment, a nanowire comprising WP₂, comprises tungsten and phosphorous an approximately 1:2 ratio. In one embodiment, a nanowire comprising NbP comprises niobium and phosphorous in an approximately 1:1 ratio.

In one embodiment, the nanowire further comprises at least one nonmetal dopant. In one embodiment, the nonmetal dopant replaces a portion of phosphorous in the nanowire. In one embodiment, the nonmetal dopant is selected from the group consisting of carbon, silicon, germanium, nitrogen, arsenic, antimony, bismuth, oxygen, sulfur, or selenium. In one embodiment, the nanowire further comprises a transition metal dopant. In one embodiment, the transition metal dopant replaces a portion of molybdenum, tungsten, or niobium in the nanowire. In one embodiment, the transition metal dopant is selected from the group consisting of titanium (Ti), vanadium (V), chromium (Cr), manganese (Mn), iron (Fe), cobalt (Co), nickel (Ni), copper (Cu), zinc (Zn) , zirconium (Zr) , niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt) , gold (Au), and mercury (Hg).

In some embodiments, the nanowire interconnect further comprises a liner, wherein the liner fully encases the nanowire and protects the nanowire from degradation. In one embodiment, the liner comprises tantalum nitride (TaN). In one embodiment, the liner comprises manganese, ruthenium, or a combination thereof. In some embodiments, the nanowire interconnect does not include a liner. In some embodiments, the nanowire interconnects described herein are more stable to oxidation and other degradative conditions than convention interconnects comprising copper, ruthenium, or gold.

In one embodiment, the nanowire has a resistivity of less than 50 μΩ·cm at room temperature. In one embodiment, the nanowire has a resistivity of less than 40 μΩ·cm at room temperature. In one embodiment, the nanowire has a resistivity of less than 30 μΩ·cm at room temperature. In one embodiment, the nanowire has a resistivity of less than 20 μΩ·cm at room temperature. In one embodiment, the nanowire has a resistivity of less than 10 μΩ·cm at room temperature. In one embodiment, the nanowire has a resistivity of approximately 10 μΩ·cm at room temperature. In one embodiment, the resistivity of the nanowire decreases asymptotically as diameter decreases. In one embodiment, the change in resistivity as a function of diameter is negligible at diameters less than 45 nm. The resistivity of a single crystal MoP nanowire is much lower than an effective copper nanowire having a comparable diameter.

In one embodiment, the nanowire demonstrates superior stability to oxidation. In one embodiment, the nanowire demonstrates little to no surface oxidation. In one embodiment, nanowires of the present invention, when exposed to ambient laboratory conditions for 48 hours, demonstrate no increase in resistance, in stark contrast to Cu interconnects.

### Devices of the Invention

In one aspect, the present invention relates to a device comprising a nanowire interconnect described herein. The nanowire interconnect described herein can be utilized in a wide variety of applications including, for example, integrated circuits and components such as flexible capacitors and self-powered sensors, nanoelectronics, photonics, environmental applications such as photocatalysts, renewable energy applications such as photovoltaic cells, and biologic applications such as sensors for detecting indicators of cancer. The nanowire interconnect described herein can be utilized in the manufacturing of integrated circuit components, including but not limited to, transistors, resistors, capacitors, diodes, and any other suitable components or combinations thereof. The integrated circuit components employing the nanowire interconnect can be utilize in any suitable integrated circuit including, but not limited to, amplifiers, oscillators, timers, counters, converters, logic gates, memory, microcontrollers, and microprocessors. In one embodiment, the device is a microchip. In one embodiment, the interconnects described herein can replace any on-chip Cu interconnects, such as in M0 and M1 stacks.

### Methods of Making

In one aspect, the present invention relates to a method of making a topological semimetal nanowire. The method comprises the steps of providing a template nanowire; providing a phosphine source; producing phosphine from the phosphine source; and contacting the template material with the phosphine.

In one embodiment, the template material is a nanowire. In one embodiment, the template nanowire comprises molybdenum, niobium, or tungsten. In one embodiment, the template nanowire comprises molybdenum oxide, tungsten oxide, or niobium oxide. In one embodiment, the template nanowire comprises molybdenum trioxide (MoO₃).

The template nanowire may be produced using any method known in the art. In some embodiments, the template nanowire may be first be grown on SiOₓ/Si substrates by the chemical vapor deposition (CVD) of MoO₃ precursors or the oxidation of Mo powders. MoO₃ nanoflakes may be synthesized by heating Mo powder to 900° C. for 1 hour in air, and MoO₃ nanowires may be grown by CVD.

In one embodiment, the size of the template nanowire corresponds to the size of the resulting topological semimetal nanowire. For example, when a MoO₃ nanowire having a diameter of less than 10 nm to 300 nm is used as the starting material a MoP nanowire having a diameter of less than 10 nm to 300 nm is produced.

In one embodiment, the template nanowire has a diameter less than 100 nm. In one embodiment, the template nanowire has a diameter less than 90 nm. In one embodiment, the template nanowire has a diameter less than 80 nm. In one embodiment, the template nanowire has a diameter less than 70 nm. In one embodiment, the template nanowire has a diameter less than 60 nm. In one embodiment, the template nanowire has a diameter less than 50 nm. In one embodiment, the template nanowire has a diameter less than 40 nm. In one embodiment, the template nanowire has a diameter less than 30 nm. In one embodiment, the template nanowire has a diameter less than 20 nm. In one embodiment, the template nanowire has a diameter less than 10 nm.

In one embodiment, the template nanowire has a diameter between 10 nm and 100 nm. In one embodiment, the template nanowire has a diameter between 10 nm and 90 nm. In one embodiment, the template nanowire has a diameter between 10 nm and 80 nm. In one embodiment, the template nanowire has a diameter between 10 nm and 70 nm. In one embodiment, the template nanowire has a diameter between 10 nm and 50 nm. In one embodiment, the template nanowire has a diameter between 10 nm and 40 nm. In one embodiment, the template nanowire has a diameter between 10 nm and 30 nm. In one embodiment, the template nanowire has a diameter between 10 nm and 20 nm.

In one embodiment, the template nanowire has a diameter of about 50 nm, about 45 nm, about 40 nm, about 35 nm, about 30 nm, about 25 nm, about 20 nm, about 15 nm, or about 10 nm.

In one embodiment, the step of providing a template nanowire comprises the step of placing the template nanowire in an apparatus for chemical vapor deposition (CVD). In one embodiment, the step of providing a phosphine source comprises the step of placing the phosphine source upstream from the template nanowire in the CVD apparatus.

In one embodiment, the phosphine source is a material which, upon exposure to heat and hydrogen gas, results in the production of phosphine gas (PH₃). In one embodiment, the phosphine source comprises a hypophosphite salt. Exemplary hypophosphite salts include, but are not limited to, alkali metal hypophosphites such as sodium hypophosphite, potassium hypophosphite, lithium hypophosphite, rubidium hypophosphite, cesium hypophosphite, ammonium hypophosphite and mixtures and/or solvates thereof. In one embodiment, the phosphine source is red phosphorous.

In one embodiment, the step of producing phosphine from the phosphine source comprises the step of exposing the phosphine source to hydrogen gas at a temperature greater than 200° C., greater than 300° C., greater than 400° C., greater than 500° C., greater than 600° C., greater than 700° C., or about 700° C. In one embodiment, the temperature is less than or equal to 800° C. In one embodiment, the reduction of the phosphine source results in the production of phosphine (PH₃). In one embodiment, the reaction between the metal oxide nanostructures and PH₃ converts the oxide to phosphide nanostructures. To obtain MoP nanostructures with different morphologies and configurations, conversion conditions such as the temperature, reaction time, H₂ gas flow rate, and P-containing precursors may be varied.

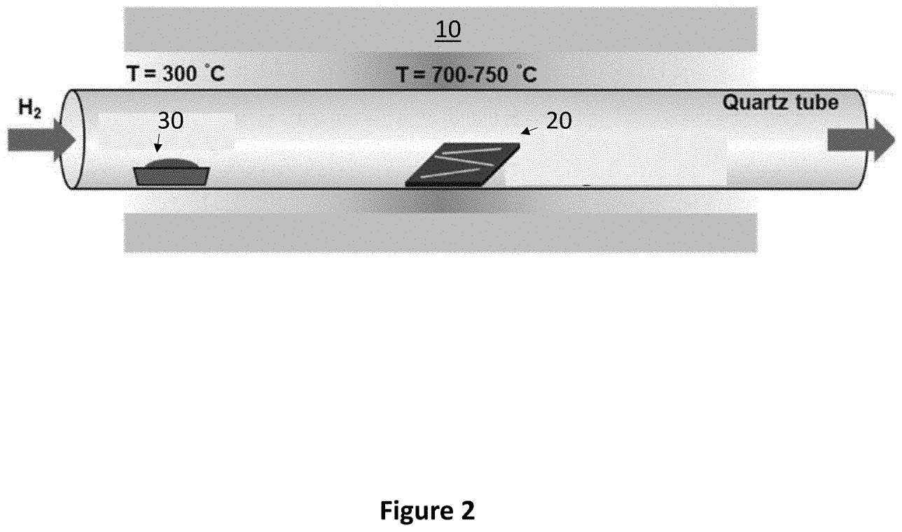

Referring to FIG. 2, in one exemplary method the template nanowire is placed on a substrate 20 are placed in the center of tube furnace 10. The phosphine precursor 30 is placed upstream, for example approximately 15 centimeters (cm) away from the center. The tube furnace 10 is heated to a temperature for example greater than or equal to 700° C. with a constant flow of H₂ gas, leading to generation of PH₃ gas. The reaction between the metal oxide nanostructures and PH₃ converts the oxide to phosphide nanostructures. To obtain MoP nanostructures with different morphologies and configurations, conversion conditions such as the temperature, reaction time, H₂ gas flow rate, and P-containing precursors may be varied.

### EXPERIMENTAL EXAMPLES

The invention is now described with reference to the following Examples. These Examples are provided for the purpose of illustration only, and the invention is not limited to these Examples, but rather encompasses all variations that are evident as a result of the teachings provided herein.

### Example 1: Synthesis and Application of MoP Nanowires

Topological semimetal nanostructures can comprise MoP, WP₂, and NbP. MoP, WP₂, and NbP nanostructures may be synthesized by converting a metal oxide nanostructures, for example MoO₃ nanostructures. using a horizontal tube furnace 10, shown schematically in FIG. 2. Throughout the remainder of the description, MoO₃ is used as an example for the topological semimetals with the understanding and appreciation that minor adjustments may be needed for WP₂, and NbP nanostructure synthesis and characterization. MoO₃ nanostructures may first be grown on SiOₓ/Si substrates by the chemical vapor deposition (CVD) of MoO₃ precursors (J. M. Woods, D. Hynek, P. Liu, M. Li, and J. J. Cha, ACS Nano 13 (6), 6455 (2019)) or the oxidation of Mo powders. MoO₃ nanoflakes may be synthesized by heating Mo powder to 900° C. for 1 hour in air, and MoO₃ nanowires may be grown by CVD as detailed in H. J. Han, et al. APL Materials 8, 011103 (2020).

MoO₃ containing substrates 20 are placed at the center of the tube furnace 10 and phosphorus containing precursors 30 placed upstream, approximately 15 centimeters (cm) away from the center. The tube furnace 10 is heated to a temperature greater than or equal to 700° C. with a constant flow of H₂ gas, leading to generation of PH₃ gas. The reaction between the metal oxide nanostructures and PH₃ converts the oxide to phosphide nanostructures. To obtain MoP nanostructures with different morphologies and configurations, conversion conditions such as the temperature, reaction time, H₂ gas flow rate, and P-containing precursors may be varied.

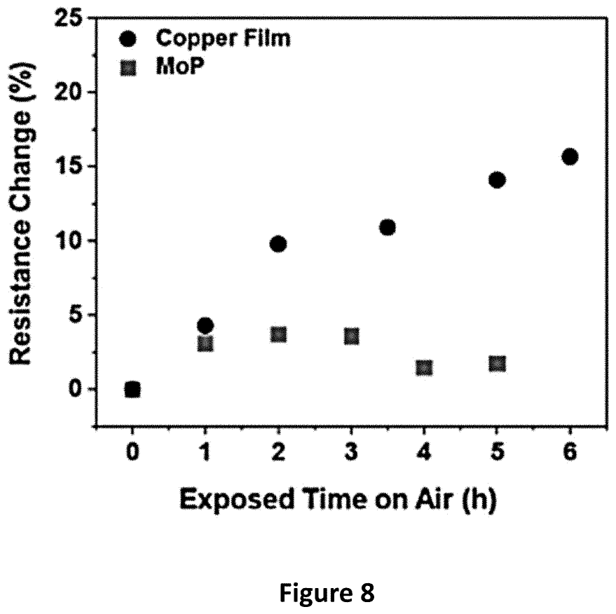

Additionally, the environmental effect on resistance has been examined. MoP nanowires exposed to air for five hours show no increase in resistance. This is in contrast to copper film which shows an increase in resistance after exposure to air for five hours. FIG. 8 is a graph demonstrating this comparison.

MoO₃ nanowires were grown by CVD. 0.15 g of MoO₃ source powder (Sigma-Aldrich, 99.95%) was placed at the center of a 1-inch tube furnace with [100] Si substrates located 15 centimeters downstream. After purging with Ar, the system was pumped down to 100 mTorr, then H₂ was flowed at 20 sccm, bringing the furnace pressure to 5 Torr. The furnace was heated to 600° C. in 15 min and held at that temperature for 10 min to produce MoO₃ nanowires with high yield.

The microstructure of the MoO₃ nanostructures was characterized by transmission electron microscopy (TEM) which showed that they were single crystalline.

### Synthesis of MoP Nanowires via Conversion from MoO₃ Nanowires

MoP nanowires were synthesized by converting MoO₃ nanowires. MoO₃ nanowires were placed in a tube furnace with a sufficient amount (2 g) of NaH₂PO₂.H₂O (Sigma-Aldrich, ≥99%) placed upstream. After purging with H₂ (200 sccm, >20 min), H₂ was flowed at 10 sccm at atmospheric pressure. The furnace was heated to 700° C. in 30 min, held there for 1 hour, then cooled down to room temperature naturally.

### Synthesis of Single Crystal Nanowires Using a Liquid Metal Substrate

MoP single crystal nanowires were synthesized by placing molybdenum foil with liquid gallium metal on the molybdenum foil in a tube furnace with a sufficient amount (25-300 mg) of NaH₂PO₂.H₂O (Sigma-Aldrich, ≥99%) placed upstream. After purging with H₂ (200 sccm, >20 min), H₂ was flowed at 10 sccm at atmospheric pressure. The furnace was heated to 1050-1100° C. in 30 min, held there for 1 hour, then cooled down to room temperature naturally. Smaller amounts of the phosphorous source resulted in a single crystal with less length.

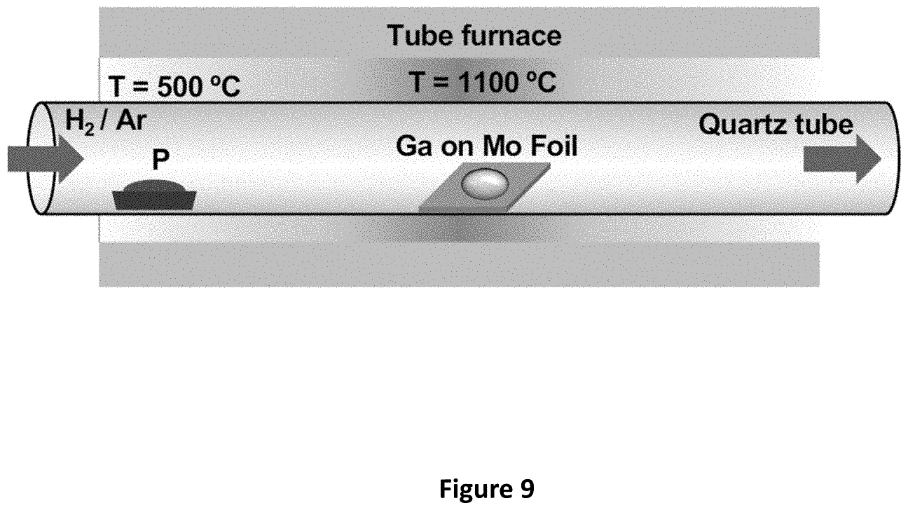

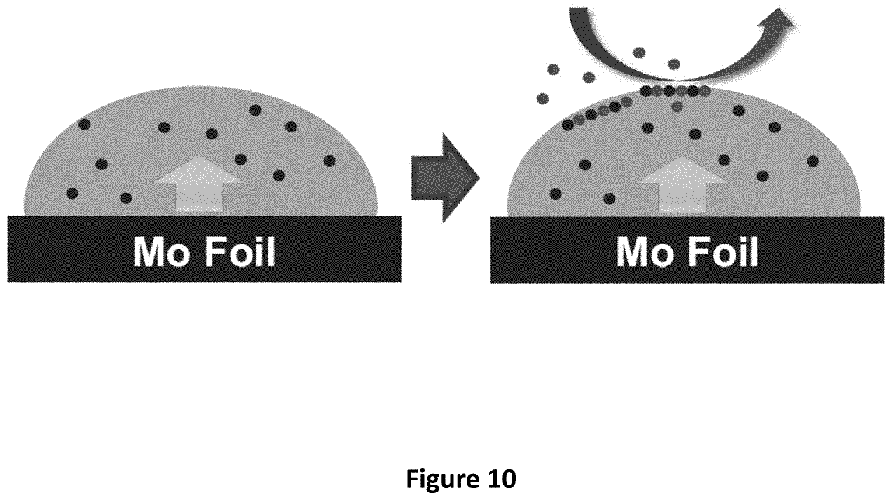

FIG. 9 shows a tube furnace having a molybdenum/liquid metal system (gallium metal on molybdenum foil) placed at the center of the tube furnace and phosphorus containing precursors placed upstream, approximately 15 centimeters (cm) away from the center. Indium could also be used in place of or in addition to gallium. The tube furnace is heated to a temperature greater than or equal to 700° C. with a constant flow of H₂ gas, leading to generation of PH₃ gas. In the molybdenum/liquid metal system molybdenum diffuses through the liquid metal to the top of the liquid metal where it reacts with the PH₃ gas to form a single crystal MoP nanowire as shown in FIG. 10. While FIG. 10 shows molybdenum foil it is contemplated that any solid form of molybdenum metal could be used such as molybdenum powder. The amount of phosphorus precursor can affect the amount of PH₃ gas produced. The amount of PH₃ gas present can be used to control the length of the single crystal MoP nanowire. Resistivity of single crystal MoP nanowires is markedly lower than polycrystalline MoP nanowires. The measured resistance for a single crystal MoP nanowire was 1 Ohm. Single crystal nanowires made by this method may have diameters greater than or equal to 100 nanometers, or, greater than or equal to 200 nanometers, or, greater than or equal to 300 nanometers.

### Structure and Chemical Characterizations

The morphology and chemical composition of the samples were characterized by scanning electron microscopy (SEM, Hitachi SU8230) with an acceleration voltage of 10 kV and a working distance of 5 millimeters (mm), as well as transmission electron microscopy (TEM, FEI Tecnai Osiris 200 kV) and X-ray diffraction (D/Max 2500; Rigaku). Atomic force microscopy (AFM) was performed with a Bruker Dimension Fastscan AFM using Fastscan B AFM tips (Bruker) at a scanning rate of 0.5-1.0 Hz.

When larger MoO₃ nanostructures are converted to MoP nanostructures a change in morphology may be seen. The change in morphology of the nanostructures after conversion may be attributed to the different crystal structure of MoO₃ and MoP. Thermodynamically stable α-MoO₃ has an orthorhombic crystal structure with planar double layers. MoP has a WC-type hexagonal crystal structure with lattice parameters a=b=3.22 Å and c=3.19 Å, and Mo and P share the same coordination environment and coordination number of six in a trigonal prism. The change in crystal structure and subsequent volume change during conversion may explain the observed porosity in the converted MoP nanoflakes. Unlike large flakes however, MoP nanowires converted from MoO₃ nanowires having a diameter less than 100 nanometers do not show any pores and have relatively smooth surfaces. This may be attributed to the fact that nanowires can withstand much larger volume changes and strain, just as the well-known example of the lithiation of Si nanowires, which can undergo a volume change of 400% without creating pores or cracks.

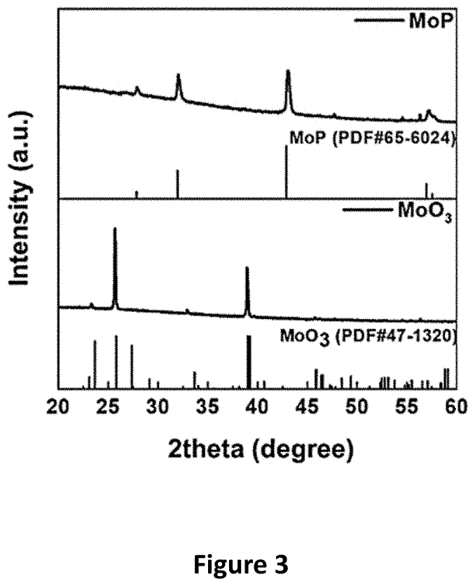

The crystal structure and chemical composition of synthesized MoP nanostructures have been confirmed by XRD. FIG. 3 shows the XRD pattern of the MoO₃ and MoP nanostructures before and after the conversion reaction. The XRD pattern from the MoO₃ nanostructures matches the standard XRD pattern of MoO₃ (JCPDS card No.47-1320), with the relative intensities of the (400) and (600) diffraction peaks being more significant, suggesting a preferred orientation during growth. After conversion, the XRD patterns of the final products show the characteristic diffraction peaks of MoP (JCPDS card No.65-6024), demonstrating the successful synthesis of MoP nanostructures. The chemical composition of the MoP has been analyzed using TEM energy-dispersive X-ray spectroscopy (EDS). Mapping of the Mo, P, and O elements showed the homogeneity of the composition.

The microstructure and crystal structure of MoP nanostructures have been also characterized by TEM. In the case of a nanoflake, TEM shows the porous nature of the MoP flake with large crystalline grains reflected in the selected area electron diffraction (SAED) pattern. The spacing of the lattice fringes observed in a high-resolution TEM image was measured to be 0.21 nm, corresponding to the (101) plane of MoP. Unlike the nanoflakes, MoP nanowires may not have pores and may contain several grains along the length of the nanowires. The lattice spacing along the axis of the nanowire was found to be 0.32 nm, corresponding to the (001) plane of MoP. The crossover from porous to non-porous MoP nanostructures occurs at the width of ˜100 nm; MoP nanowires with diameters <100 nm do not contain pores. Interestingly, MoP nanowires made from MoO₃ with diameters less than 10 nm are single crystalline. This can be explained by the nanoscale confinement effect, where the lack of nuclei and the prohibitively high energy cost of grain boundaries at the nanoscale result in single-crystalline rather than poly-crystalline grains. MoP nanowires made on a liquid metal substrate are single crystalline and have diameters greater than 100 nanometers, or greater than 200 nanometers, or greater than or equal to 300 nanometers.

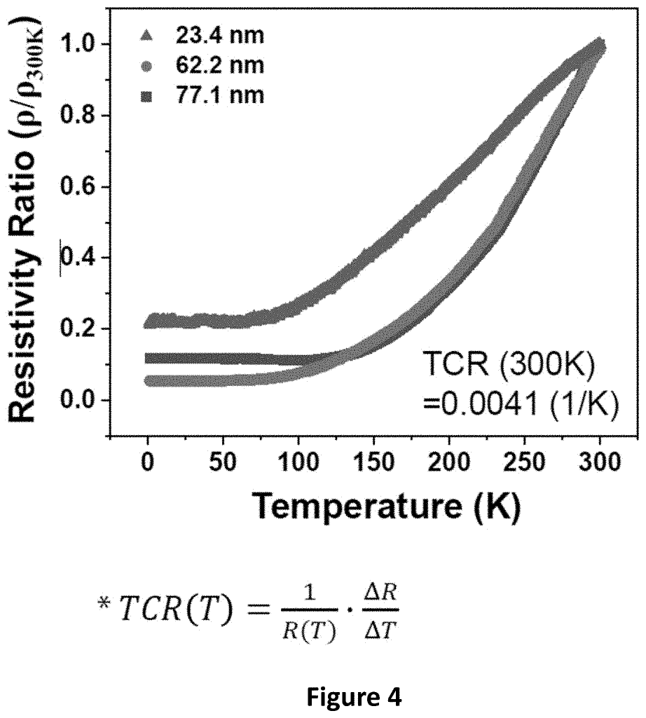

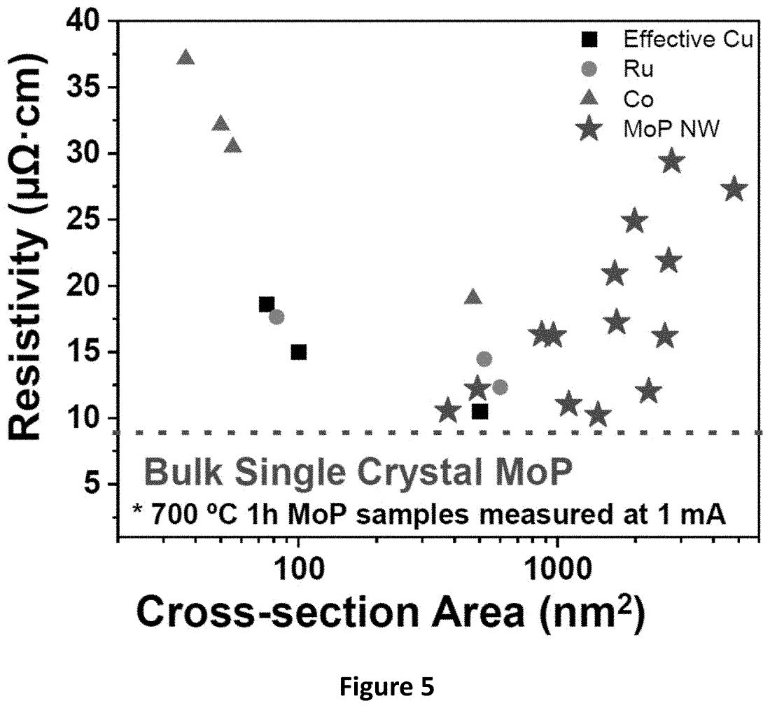

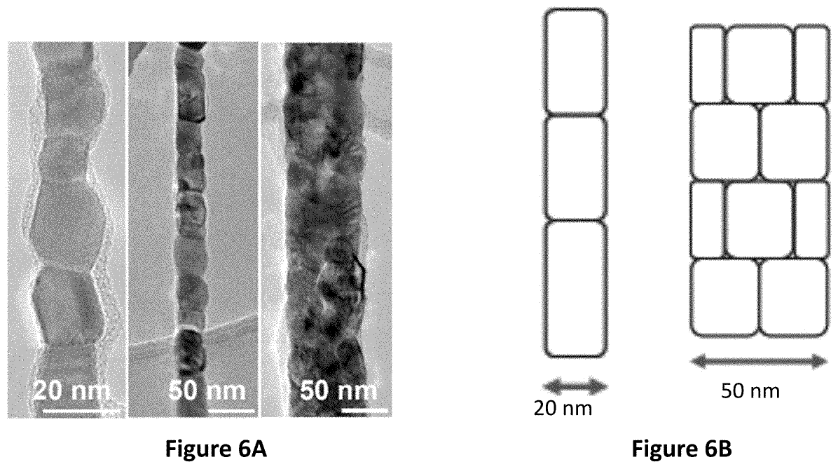

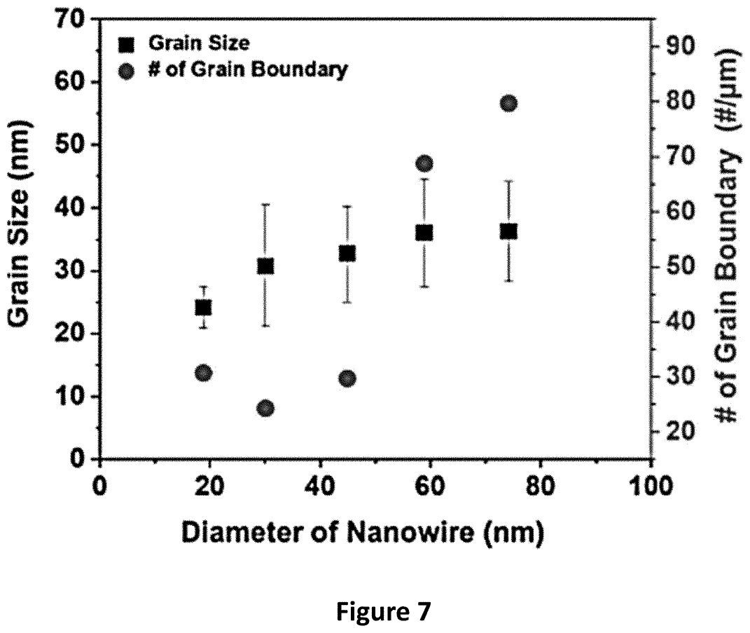

MoP nanowires show metallic behavior despite being polycrystalline as shown in FIG. 4. The resistivity of polycrystalline MoP nanowires having different cross-sectional areas at room temperature is comparable to nanowires of effective copper, cobalt and ruthenium as shown in FIG. 5. FIG. 6A shows a TEM image of an exemplary 20 nm polycrystalline nanowire and two TEM images of an exemplary 50 nm nanowire, one with greater magnification than the other. FIG. 6B shows a drawing of the crystallite arrangement of the nanowire shown in the micrographs. The average grain size and the number of grain boundaries for a number of polycrystalline nanowires having different diameters are shown in FIG. 7. A comparison of the number of grain boundaries to the resistivity indicates that a smaller number of grain boundaries means more consistent resistivity between nanowires.

### Calculation of Grain Size

The average size of the grains of the MoP nanowires was determined by analyzing TEM images and XRD peaks using the Scherrer equation, D=k·λ/β·cosθ, where k is the shape factor (k=0.89), λ is the X-ray wavelength (λ=1.5418 Å for Cu kα radiation), θ is the Bragg diffraction angle (in degrees) and β is the full width at half maximum of the peak (101).

Grain size as a function of nanowire diameter was analyzed, as shown in FIG. 7. Nanowires are observed to be single crystalline when their diameters were below 10 nm. Nanowires were polycrystalline and non-porous when their diameters ranged between 10 and 100 nm. For these nanowires, the average grain size increased with increasing nanowire diameter until it reached an asymptotic value of ˜20 nm. The grain size was also studied as a function of growth conditions by analyzing the XRD (101) peak using Scherrer's equation. The grains became larger at higher reaction temperatures, which can be expected due to coarsening.

### Device Fabrication and Transport Measurements

The synthesized MoP nanowires were transferred onto SiO₂/Si substrates by polymer stamping and coated with a double layer e-beam resist (˜700 nm MMA EL 8.5 as the first layer and ˜200 nm PMMA A4 as the second layer). Electrode patterns were fabricated by standard e-beam lithography using a Vistec EBPG 5000+. The devices were designed for four-probe measurements, and the gap between the electrode was kept around 200-300 nm for all nanostructures measured. After the pattern was developed, 5/100 nm-thick Cr/Au electrical contacts were deposited by thermal evaporation (MBraun MB-EcoVap). Transport measurements at low temperature were performed using a Quantum Design Dynacool physical property measurement system equipped with a base temperature of 2 K. Resistance scans were taken as a function of temperature at an applied current value of 100 nA.

### MoO₃/MoP Phase Diagram

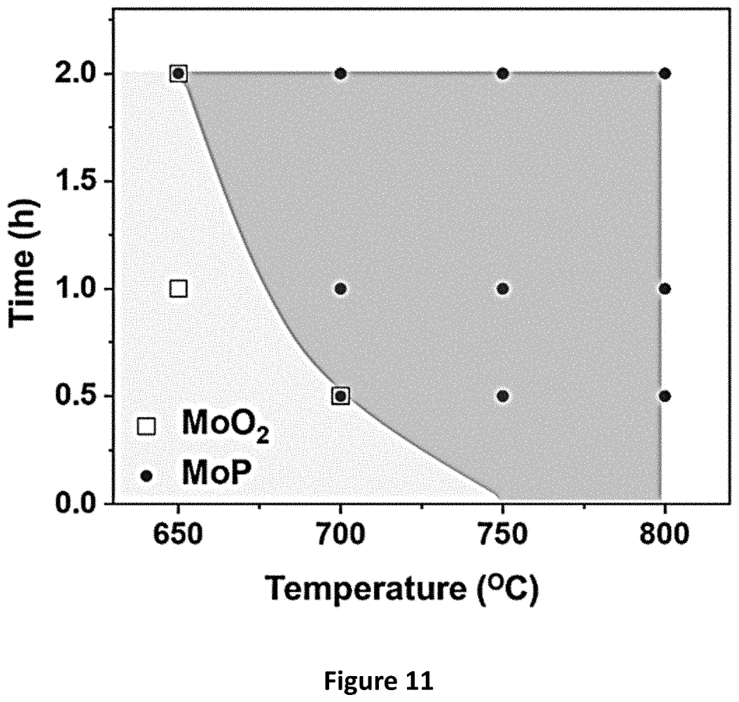

The reaction conditions of the MoO₃ to MoP conversion were systematically varied and then used XRD to map out the phase diagram, as shown in FIG. 11. At a lower reaction temperature (650° C.) and 1 hour reaction time, the product shows typical peaks of MoO₂ (JCPDS card No. 32-0671), but no distinct characteristic peaks of MoP. At 700° C. for a reaction time of 0.5 hour, the product shows typical peaks of MoO₂ and MoP, and when the reaction time is increased to 1 hour, MoP peaks appear, while the peaks of MoO₂ disappear. At higher reaction temperatures (750-800° C.), XRD patterns indicate MoP nanostructures for all reaction times (0.5, 1, and 2 hours). In other words, higher reaction temperatures of 700° C. and above result in a more efficient conversion of MoO₃ to MoP, while reaction temperatures less than 700° C. do not promote this transition well. Moreover, the degrees of reactivity depend on the choice of P-containing precursors, which can be modulated by the flow rate of H₂ gas and leads to the co-presence of MoO₂ and MoP in the synthesis. For example, the flow rate of H₂ influenced the yield ratio of MoP and MoO₂ products for red phosphorus precursors, but it did not influence the yield ratio for NaH₂PO₂.H₂O precursors.

### Example 2: Topological Metal MoP Nanowire for Interconnect Applications

The increasing resistance of Cu interconnects for decreasing dimensions is a major challenge in continued downscaling of integrated circuits beyond the 7-nm technology node as it leads to unacceptable signal delays and power consumption in computing. The resistivity of Cu increases due to electron scattering at surfaces and grain boundaries of the interconnects at the nanoscale. Topological semimetals, owing to their topologically protected surface states and suppressed electron backscattering, are promising material candidates to potentially replace current Cu interconnects as low-resistance interconnects. Here, the attractive resistivity scaling of topological metal MoP nanowires is explored and it is demonstrated that the resistivity values are comparable to those of Cu interconnects below 500 nm² cross-section areas. More importantly, the dimensional scaling of MoP nanowires, in terms of line resistance versus total cross-sectional area, is superior to those of effective Cu and barrier-less Ru interconnects, indicating that MoP is an attractive solution to the current scaling challenge of Cu interconnects.

In this work, systematic engineering and dimensional resistivity scaling of poly-crystalline MoP nanowires is reported through the template assisted chemical vapor deposition (CVD) and it is demonstrated that MoP nanowires exhibit dimensional scaling superior to effective Cu (Cu with TaN liner) and Ru for dimensions beyond the 7-nm technology node.

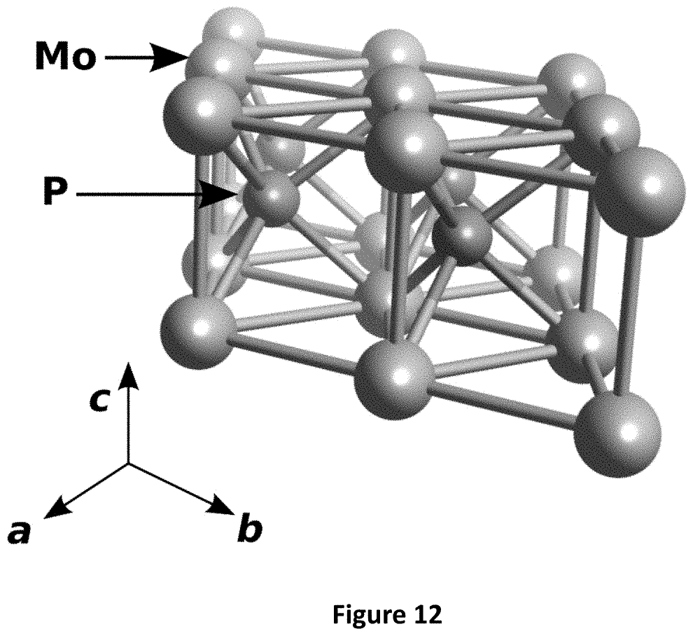

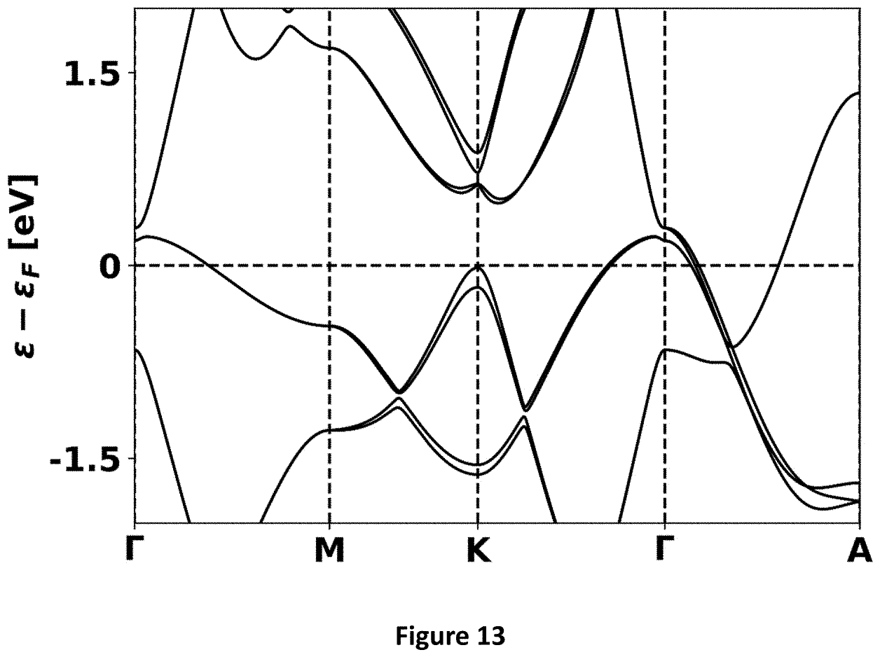

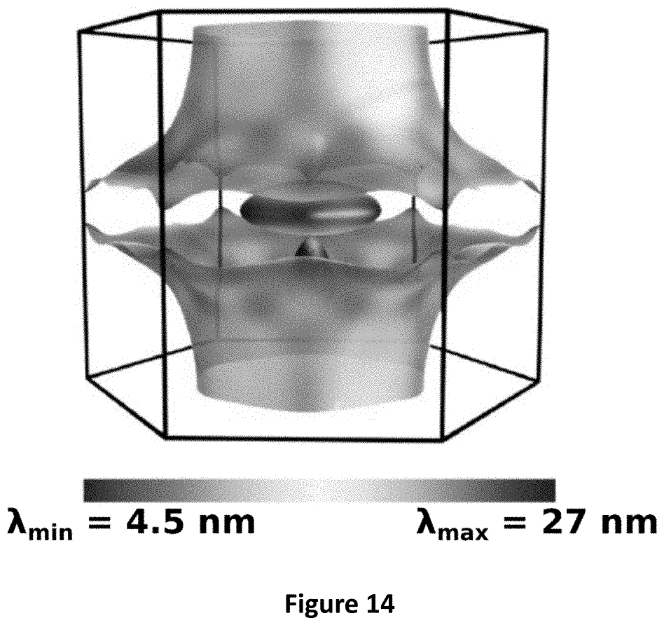

MoP has a WC-type hexagonal crystal structure (FIG. 12) with lattice parameters α=b=3.22 Å and c=3.18 Å (N. Kumar, et al. Nat. Commun. 10, 2475 (2019)). Mo and P share the same coordination number and coordination environment of six in a trigonal prism. Ab initio calculations show the presence of topologically protected triple point fermions roughly 0.7 eV below the Fermi level along the Γ-A high symmetry k-point path in the Brillouin zone (FIG. 13), which were verified by previously published angle-resolved photoemission spectroscopy results (B. Q. Lv, et al. Nature. 546, 627-631 (2017)). FIG. 14 shows the first-principles calculated Fermi surface of MoP along with the highly anisotropic electron-phonon mean free path distribution. While the droplet-shaped electron pockets (elongated along the Γ-A direction) are found to have the longest mean free paths, the flat hole pockets centered at Γ have the shortest mean free paths. Based on the calculated Fermi surface, the electron mean free path length of 10.5 nm and the room temperature resistivity of 12.9 μΩ·cm is computed along the α-axis and 9.8 μΩ·cm along the c-axis for bulk MoP. The mean free path of MoP is nearly four times shorter than that of Cu (40 nm), which is advantageous for interconnect applications because the dimensional increase of resistivity will not emerge until the interconnect dimension approaches the mean free path.

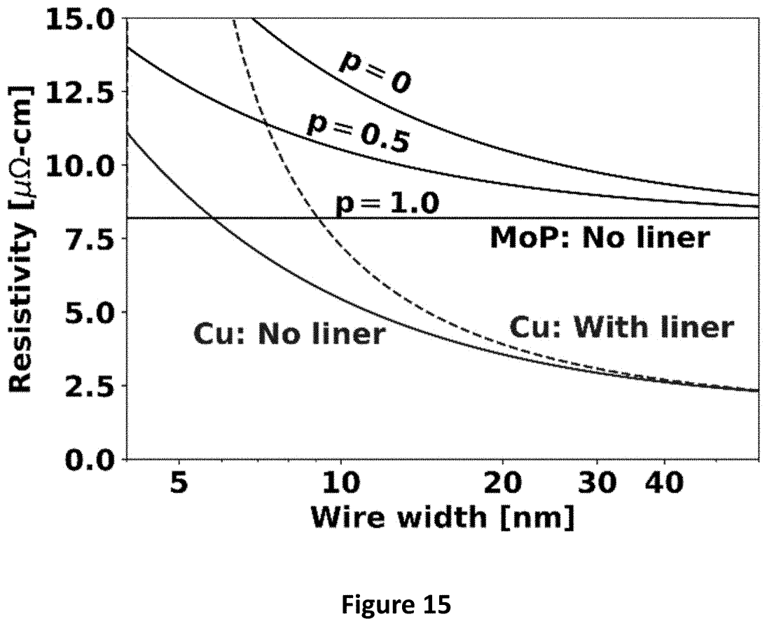

Considering electron scattering at surfaces of a square cross-section wire, the resistivity increase of MoP nanowires with decreasing wire width is calculated and compared to that of Cu using the Fuchs-Sondhemier and Mayadas-Shatzkes equation (FIG. 15). This calculation assumes single-crystalline Cu and MoP, and thus only includes electron scattering at surfaces of the wire and excludes scattering at grain boundaries. The different curves for MoP (p=0, 0.5, 1) correspond to the different values of the specularity parameter p, which is the proportion of electrons scattered elastically at the surfaces. p=1 corresponds to a perfectly smooth surface with specular reflection of electrons, while p=0 represents completely diffuse scattering. For Cu, reported values were used for surface scattering (D. Josell, et al. Annu. Rev. Mater. Res. 39, 231-254 (2009); C. Adelmann, Solid. State. Electron. 152, 72-80 (2019)) and this case represents the idealized case without grain boundary scattering. The calculations predict that MoP wires will outperform Cu wires with liner below 10 nm widths for ideal characteristics (p=1) and below 7 nm for worst-case characteristics (p=0) (more details can be found in Supporting Information). The latest 5-nm technology node contains Cu interconnects with ˜15 nm width in the M0 stack (B. Dieny, et al. Nat. Electron. 3, 446-459 (2020); S. Jones, 7 nm, 5 nm and 3 nm Logic, Current and Projected Processes. SemiWiki, June. 25 (2018) (available at https://go.nature.com/2XWfpaf)); thus, MoP represents as a promising interconnect material for future technology nodes.

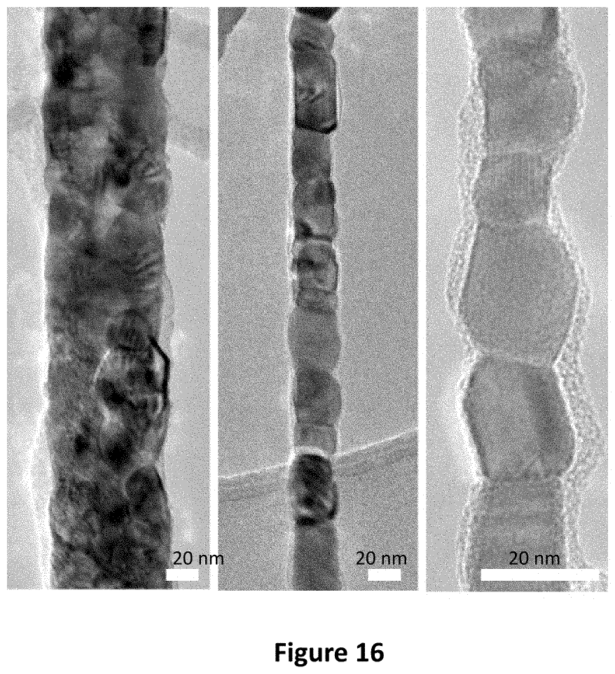

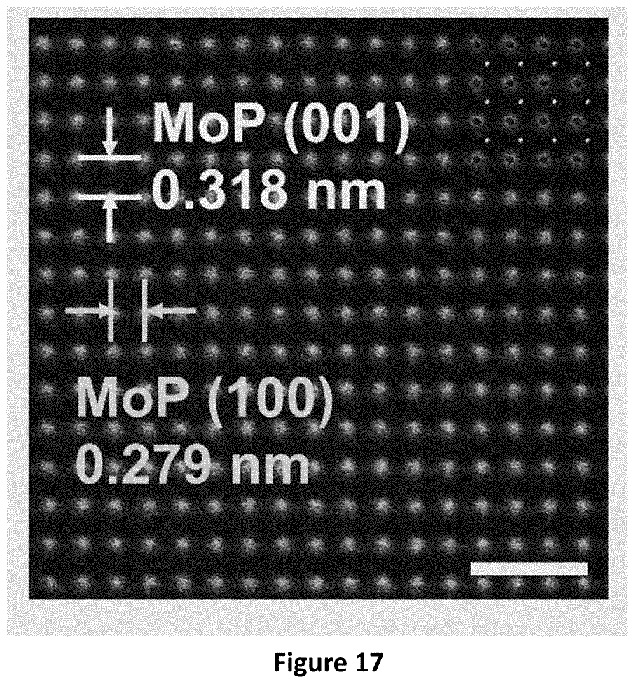

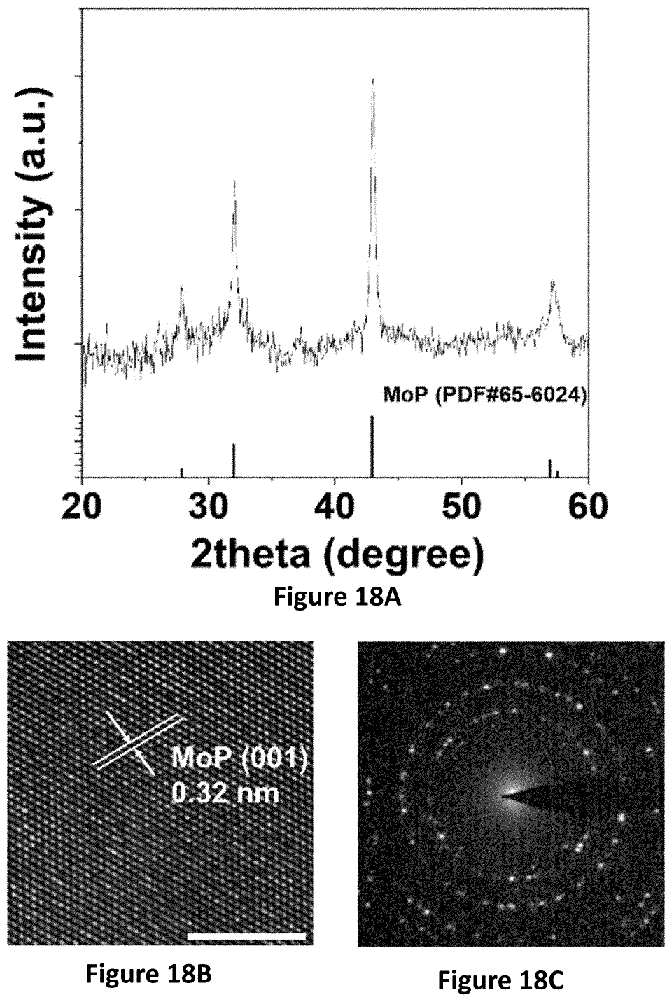

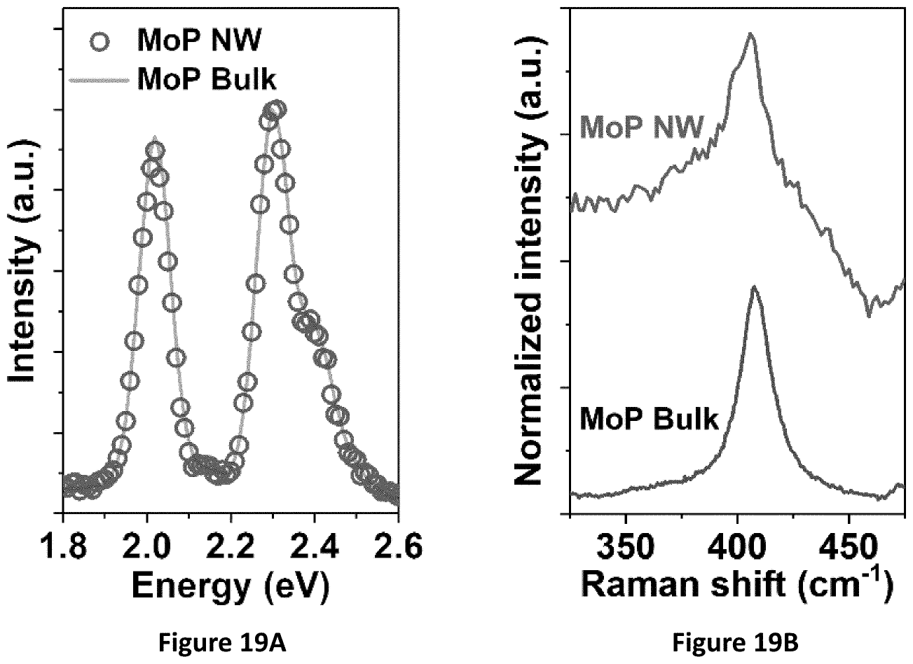

The MoP nanowires are synthesized by heating MoO₃ nanowires in the presence of PH₃ vapors and H₂ gas in a CVD system. Transmission electron microscopy (TEM) images of MoP nanowires show poly-crystalline wires (FIG. 16). FIG. 17 shows an atomic-resolution high-angle annular dark-field scanning TEM (HAADF-STEM) image of a MoP grain projected along the [010] direction, with a lattice spacing of 3.2 Å in agreement with the MoP (001) lattice spacing. Selective area electron diffraction (SAED) patterns and X-ray diffraction data (FIG. 18A, 18B, and 18C) confirm the atomic structure of MoP for the nanowires. Energy dispersive spectroscopy (EDS) analysis of the poly-crystalline nanowires indicates that the Mo:P atomic ratio is close to 1:1 as the EDS data from the nanowires overlap with that from a MoP bulk crystal grown via chemical vapor transport (CVT) (FIG. 19A). FIG. 19B shows Raman spectra taken from the MoP nanowires and bulk crystal; one main peak is resolved at ˜407 cm⁻¹, corresponding to the E mode (J. Chen, Comput. Mater. Sci. 173, 109466 (2020); F. Cao, et al. Sci. China Mater. 64, 1182-1188 (2021)).

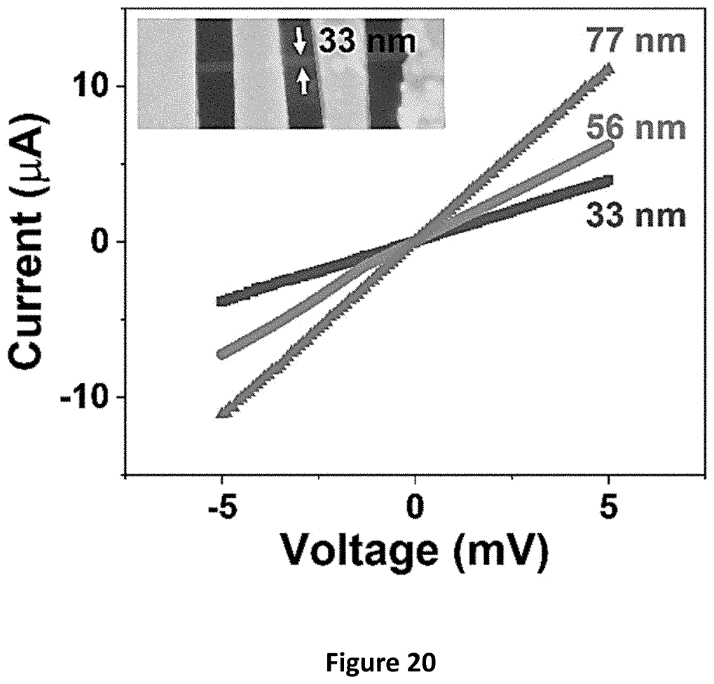

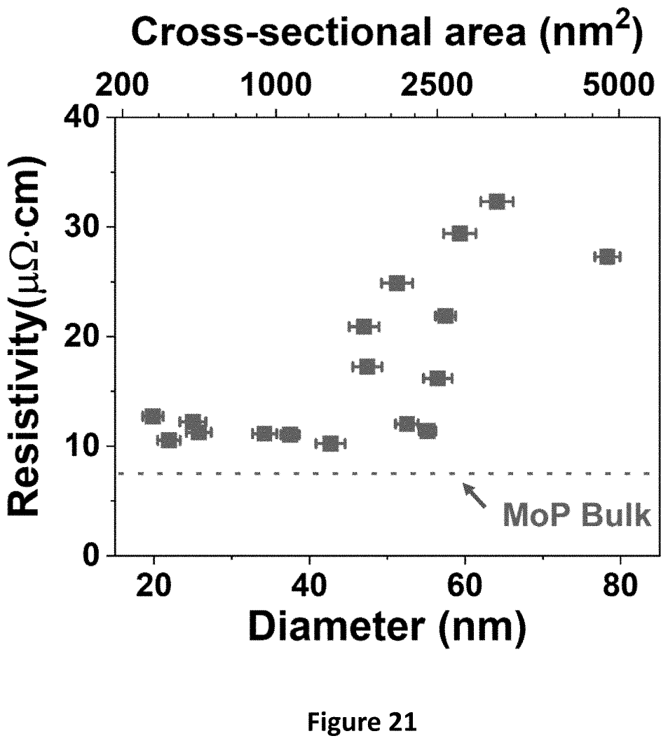

Room temperature transport properties of MoP nanowires were assayed to test the feasibility of MoP as a low-resistance interconnect material. Nanodevices were fabricated using Cr/Au contacts to measure the resistance of MoP nanowires as a function of wire diameter. FIG. 20 shows two-probe I-V curves of these MoP nanowires, which are linear and ohmic as expected for a metal. Four-probe resistance measurements were carried out to remove the contact resistance and the measured resistance was converted to resistivity where the cross-section areas of the MoP nanowires were obtained by measuring the wire diameters using scanning electron microscopy and assuming a circular cross-section. FIG. 21 summarizes the resistivity of MoP nanowires at room temperature. Remarkably, the resistivity of MoP nanowires ranges between 11 and 13 μΩ·cm for cross-section areas of 300-1500 nm², which is in agreement with the calculated resistivity and represents only ˜50% increase from the bulk resistivity of single crystal MoP (8 μΩ·cm) (N. Kumar, et al. Nat. Commun. 10, 2475 (2019)). By contrast, the resistivity of Cu interconnects with a liner at 500 nm² cross-section area increases by more than seven times from the bulk value (˜12 μΩ·cm from 1.68 μΩ·cm) (M. H. Van Der Veen, et al. 2018 IEEE Int. Interconnect Technol. Conf. IITC 2018, 172-174 (2018)). Thus, the resistivity of MoP nanowires is already as good as that of Cu interconnects in these nanoscale dimensions.

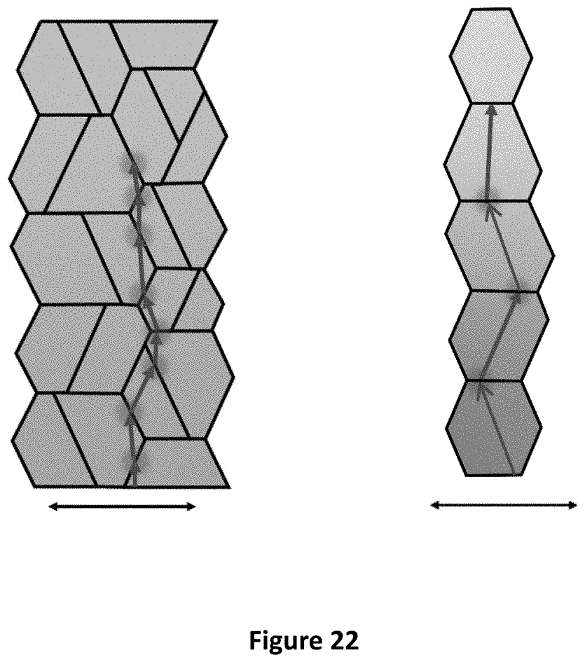

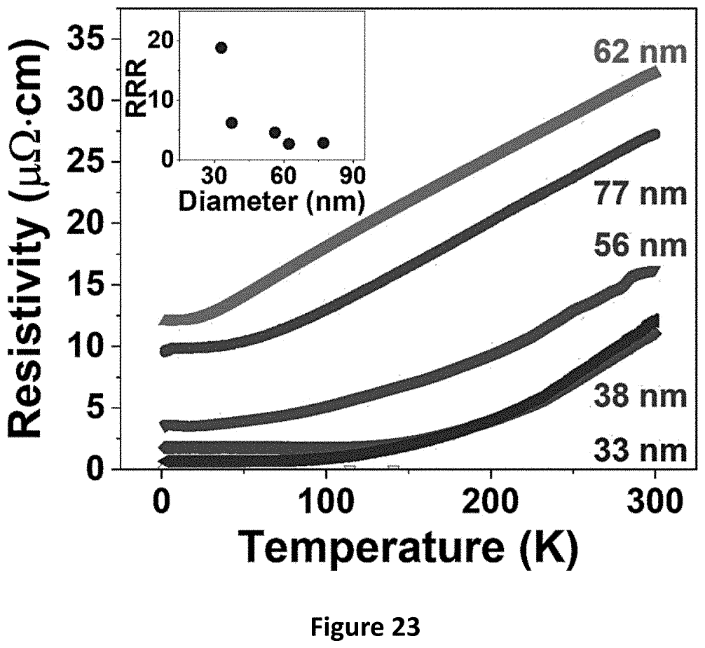

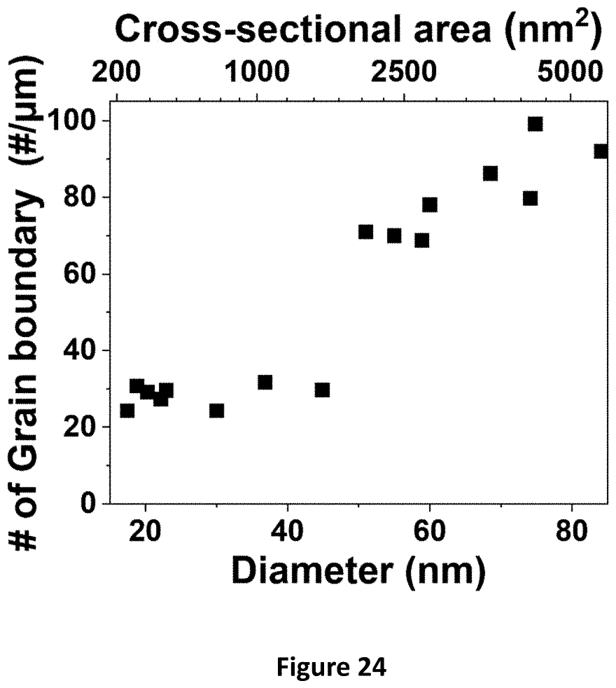

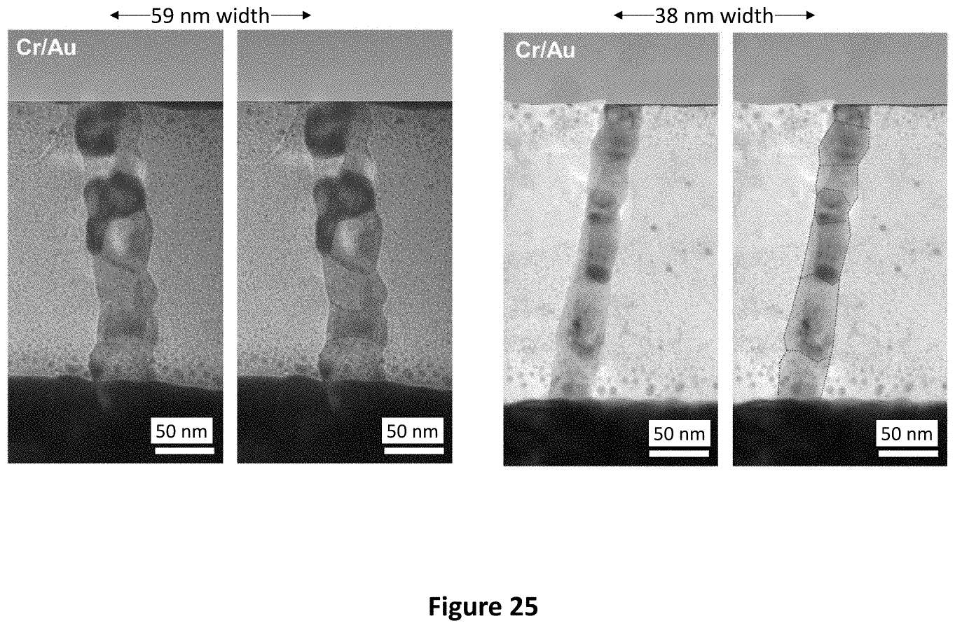

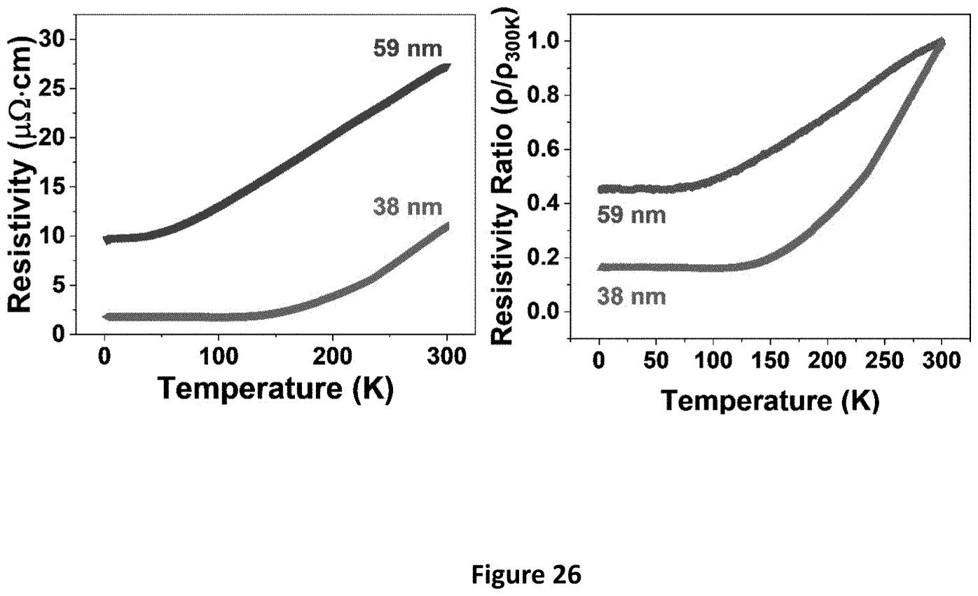

The resistivity of poly-crystalline MoP nanowires is high for large wires (˜30 μΩ·cm for 3000 nm² cross-section area in FIG. 21) and decreases asymptotically to the bulk resistivity value as the cross-section area decreases. This observation is attributed to the high number of grain boundaries present in large MoP nanowires, many of which are parallel to the direction of current flow and dramatically increase grain boundary electron scattering, as illustrated in FIG. 22. When the grain boundaries parallel to the current direction are absent, for example in small MoP wires (FIG. 16), the resistivity of MoP nanowires is close to the bulk resistivity. The diameter-dependent crystalline quality of MoP nanowires is supported by analyzing the residual resistance ratio (RRR). FIG. 23 shows the temperature dependent resistivity curves of MoP nanowires with varying diameter. The RRR decreases with increasing wire diameter (inset in FIG. 23 which supports the observed resistivity trend and agrees with the microstructure difference between large and small MoP nanowires. The microstructure difference was directly verified using TEM, where a sudden increase in the number of grain boundaries at the nanowire width of 45 nm was observed (FIG. 24), which coincides with the nanowire width at which the resistivity of MoP nanowires starts to decrease rapidly. Direct correlation between the microstructure and transport properties for two MoP nanowires are shown in FIG. 25 and FIG. 26. To further elucidate the origin of the anomalous decrease of resistivity in polycrystalline MoP nanowires with decreasing diameter, the relationship between the transport properties and the microstructure of MoP nanowires was directly established by transferring the measured devices to TEM grids. FIG. 25 shows two MoP nanowire devices with different diameters, Scale bars, 50 nm. The average grain size of the nanowire shown at left in FIG. 25 is around 42 nm and the nanowire width is 59 nm. The number of grain boundaries per unit length of this wire is thus 103.45/μm. In contrast, for the at right in FIG. 25, the average grain size is around 36 nm with the wire width of ˜38 nm, and the number of grain boundaries per unit length is 22.68/μm. The performance of the two nanowires is depicted in FIG. 26. The RRR value of the nanowire shown at right in FIG. 25 (59 nm width) is ˜2.22, whereas it is ˜6.25 for the wire shown at left (38 nm width).

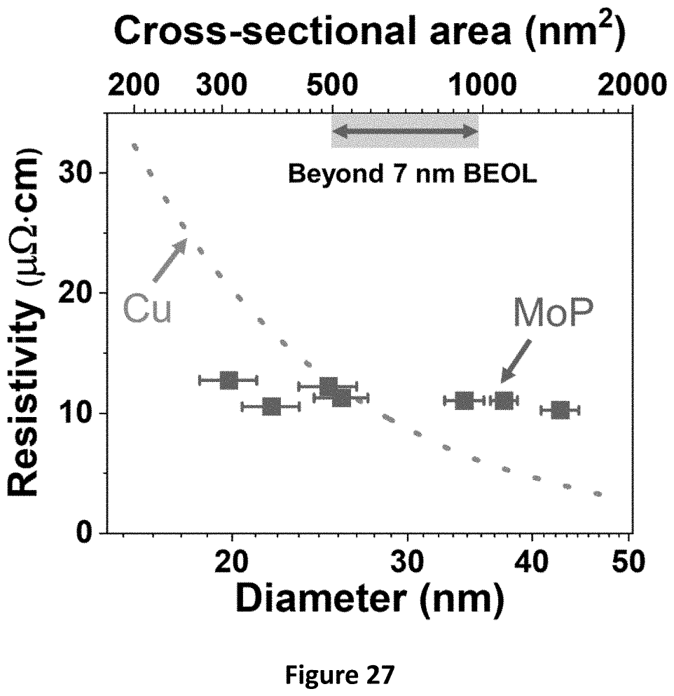

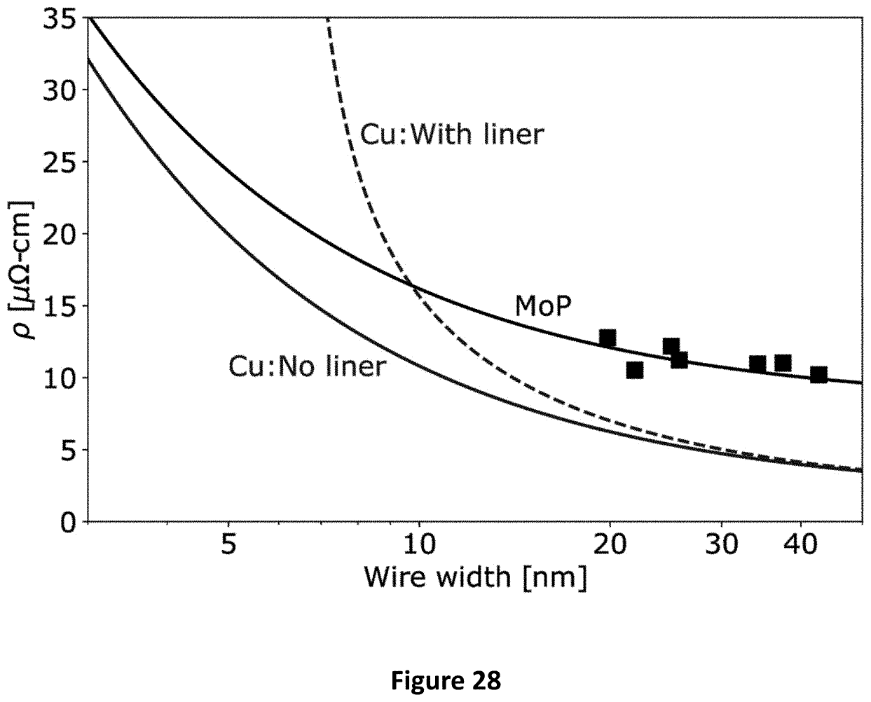

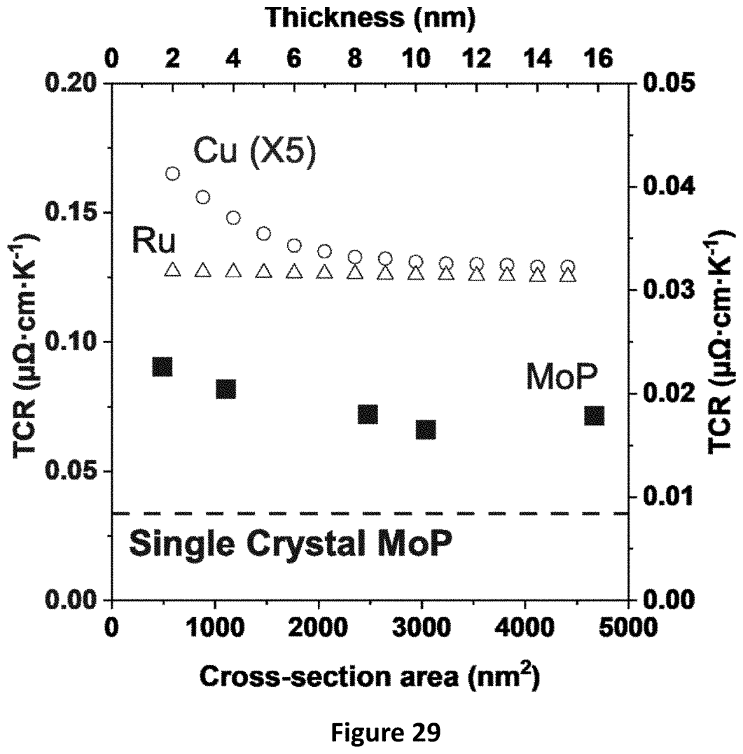

In FIG. 27, the resistivity of the best performing polycrystalline MoP nanowires are benchmarked against current state-of-art interconnect materials, such as Cu with improved liner (Mn/Ru) and barrier-less Ru for cross-section areas <1000 nm² (E. Milosevic, et al. 2018 IEEE Nanotechnol. Symp. ANTS 2018, 1-5 (2019)), which represents dimensions below the 7-nm back end of line (BEOL) technology nodes. The polycrystalline MoP nanowires show the lowest resistivity values with the best dimensional scaling behavior. The room temperature resistivity measurements thus experimentally demonstrate that electron scattering at surfaces and grain boundaries of MoP nanowires are negligible at these dimensions, in contrast to Cu, owing to the much smaller electron mean free path of MoP (10.5 nm) as compared to Cu (40 nm). The resistivity of MoP nanowires is also lower than that of Ru, the leading material candidate to replace Cu interconnects. Given the polycrystalline nature of the MoP nanowires, the calculation of the resistivity increase of the MoP and Cu nanowires was repeated with decreasing wire width and include grain boundary scattering, which shows that MoP will still outperform Cu wires with liner below 10 nm widths (FIG. 28). A comparison of temperature coefficient of resistivity (TCR) values of MoP nanowires with those of Cu and Ru reveals that electron scattering at surfaces and grain boundaries is not as detrimental for MoP as for Cu and Ru (FIG. 29). TCR is a measure of the ratio of surface electron scattering to grain boundary electron scattering. TCR values of MoP nanowires (˜0.07 μΩ·cm·K⁻¹) are larger than single crystal MoP that has no grain boundaries (1) (0.03 μΩ·cm·K⁻¹). The increase of TCR values for MoP nanowires with decreasing cross-section areas is small, which indicates reduced grain boundary scattering according to Mayadas and Shatzkes (MS) modeling. For MoP nanowires, this can be attributed to the shorter mean free path λ of MoP (8.5 nm). The y-axis on the right and x-axis at the top of FIG. 29 are for TCR values of Ru and Cu, while the y-axis on the left and x-axis at the bottom are for TCR values of MoP. Thus, this benchmark comparison suggests that MoP is superior to Cu and Ru for cross-section areas <300 nm².

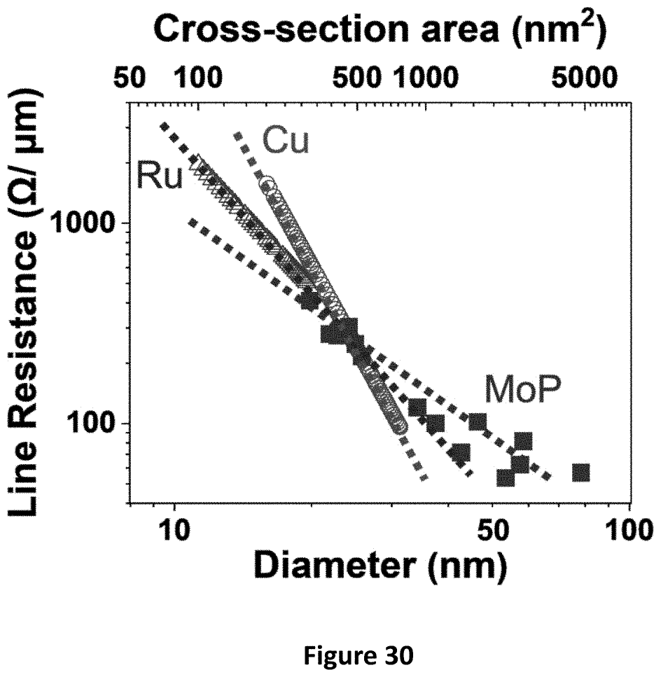

The superior dimensional scaling of MoP resistivity over effective Cu and Ru is made apparent by analyzing the line resistance. For interconnect applications, the rate of increase of line resistance needs to be as small as possible as the interconnect dimensions shrink. FIG. 30 shows the line resistance of MoP, effective Cu, and Ru as a function of the wire cross-section area, plotted in logarithmic scale. The difference in line resistance increase with decreasing wire cross-section for MoP versus Ru and Cu is clear. The dotted lines are fit to the experimental data, which show log(R) scales linearly with log(cross-section area). The fitted slope shows that the increase is most severe for Cu and least severe for MoP. Thus, MoP should outperform Cu as low-resistance interconnects below the 7-nm technology node.

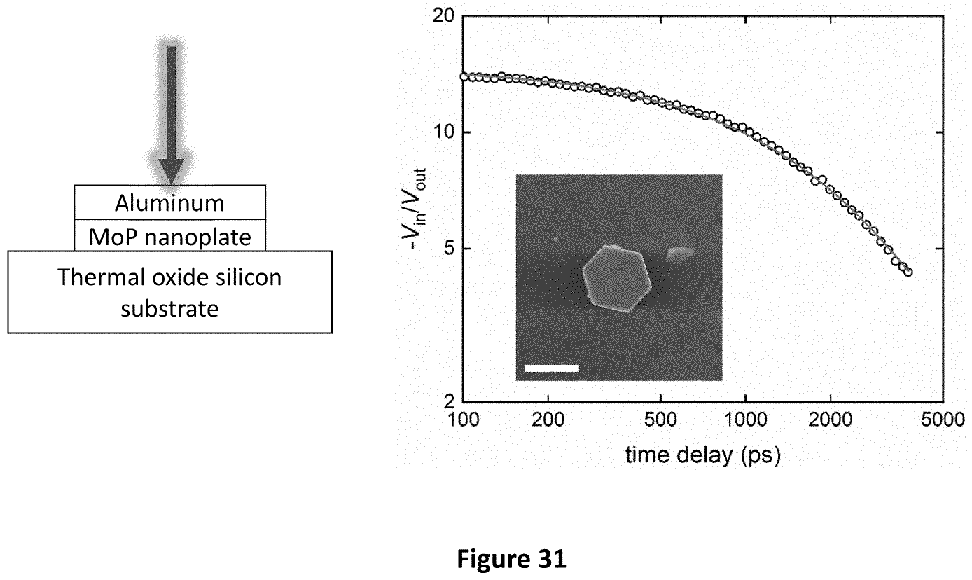

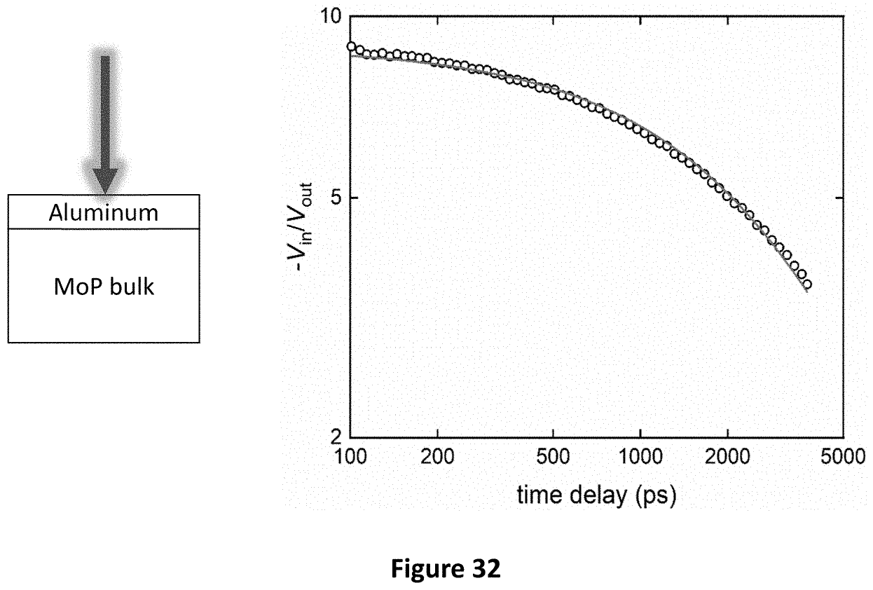

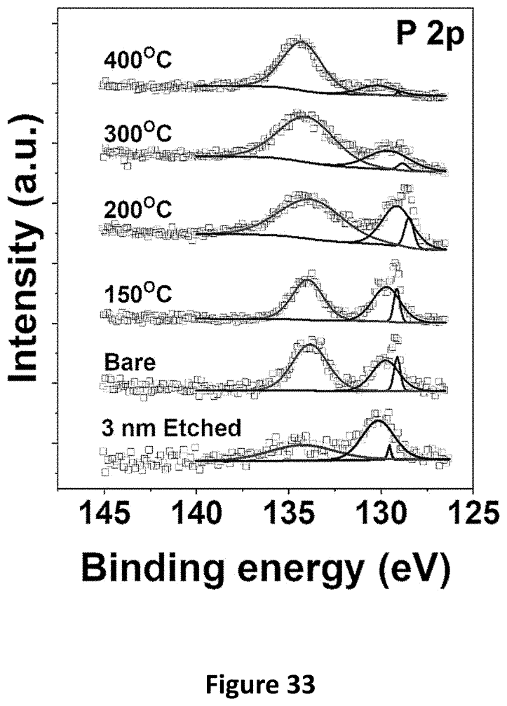

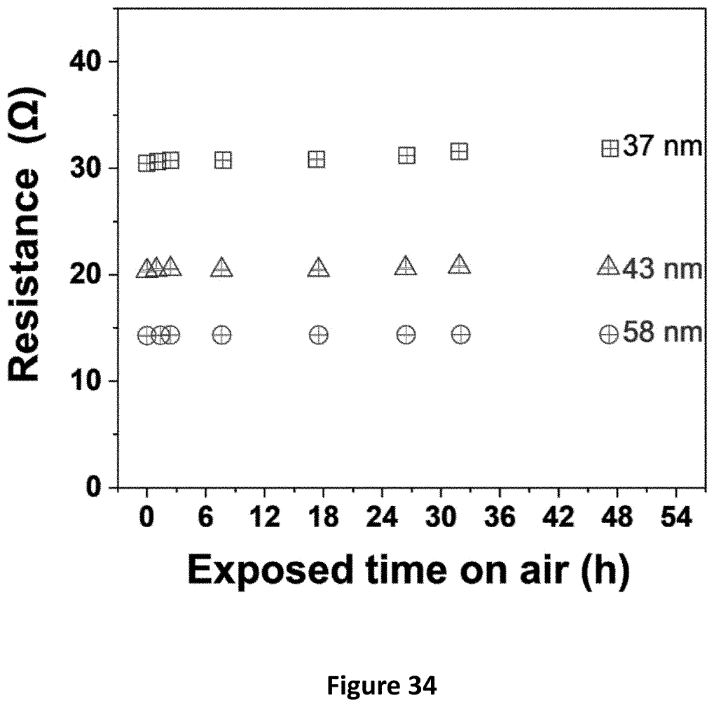

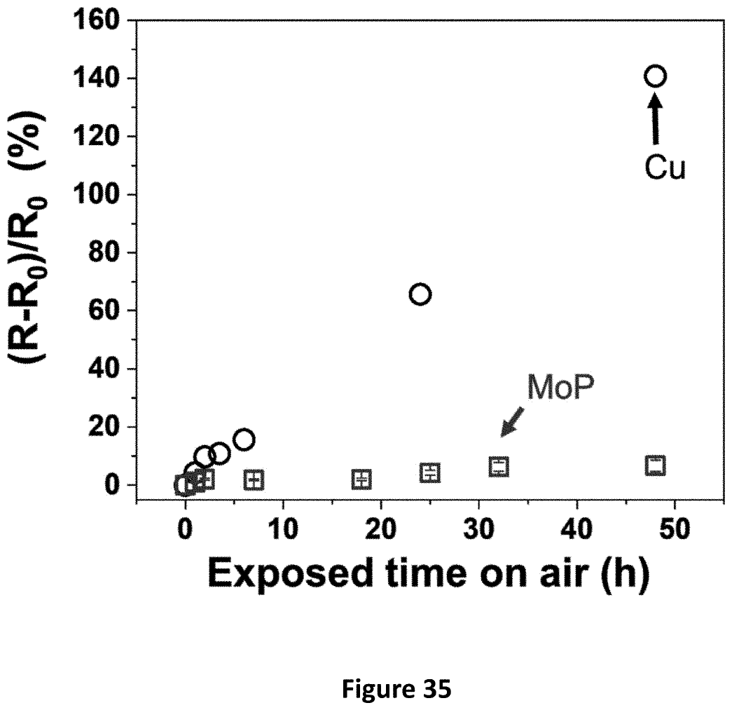

If MoP were to replace Cu in low-resistance interconnects, other materials properties must also be considered, such as surface oxidation, thermal conductivity, and electromigration. If MoP oxidizes easily or electromigrates under the application of electrical field, MoP would require a barrier layer, which is often resistive and would negate the observed attractive properties of MoP nanowires. Moreover, if the thermal conductivity of MoP is low, then effective heat management would be difficult. However, experiments detailed herein demonstrate that barrier-free MoP nanowires demonstrate superior qualities and resistance to degradation. Using time-domain thermoreflectance (TDTR), an averaged thermal conductivity of 99 W/m-K with a standard deviation of 2 W/m-K was obtained from measuring several MoP nanoplates at 300 K (FIG. 31, FIG. 32, and Table 1); the systematic uncertainty of TDTR measurements is usually 7% (Y. K. Koh, et al. J. Appl. Phys. 105, 1-8 (2009)). The measured thermal conductivity of MoP nanoplates is in good agreement with that of a CVT-grown MoP bulk crystal, which was measured to be 96 W/m-K using TDTR. These thermal conductivity values are in line with calculations, but much lower than the thermal conductivity reported by Kumar et. al. using CVT-grown MoP bulk crystals (S. D. Guo, et al. J. Phys. Condens. Matter. 29 (2017), doi:10.1088/1361-648X/aa893). For surface oxidation, the MoP nanowires were annealed in air up to 400° C. and observed negligible surface oxidation up to 150° C. based on X-ray photoelectron spectroscopy (FIGS. 34, 35, and 36). The negligible surface oxidation for MoP nanowires was confirmed by measuring the resistance of MoP nanowire devices left in ambient. The resistance did not increase for the three MoP nanowires tested (diameters of 37 nm, 43 nm, and 58 nm) over the 48 hrs they were left in ambient, while the resistance increased by 140% for a 20 nm-thick Cu film under the same condition.

TABLE 1
Thermal conductivities measured by
TDTR and thicknesses of MoP samples

| MoP | Thickness* | Thermal conductivity |
|---|---|---|
| nanoplates | (μm) | (W/m-K) |
| 1 | 4.0 | 100 |
| | | 99 |
| | | 99 |
| 2 | 3.7 | 97 |
| | | 98 |
| | | 98 |
| 3 | 2.5 | 96 |
| | | 101 |
| | | Thermal conductivity |
| MoP bulk | Thickness | (W/m-K) |
| 1 | Set infinity in | 96 |
| | data analysis | |

*Thicknesses of MoP nanoplates were determined by the Keyence VK-X1000 3D Laser Scanning Confocal Microscope in Materials Research Laboratory in University of Illinois at Urbana-Champaign.

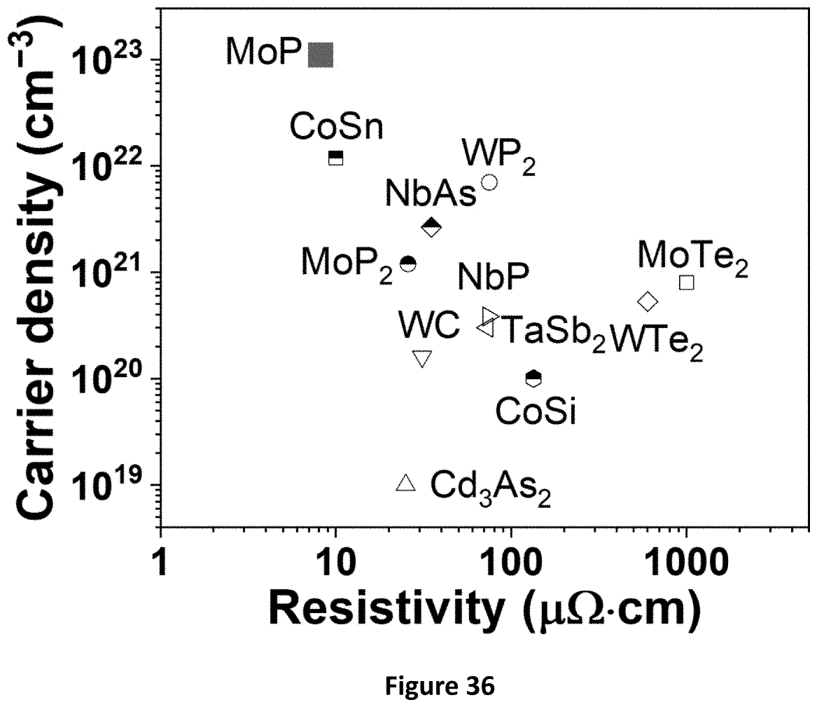

MoP has the best attributes for interconnect applications among the topological semimetals reported in literature. Reported values of room temperature transport properties of topological semimetals were surveyed. FIG. 36 summarizes the carrier density versus resistivity of topological semimetals from bulk and sub-micron samples. For interconnect applications, high carrier density and low resistivity are desirable. For this reason, topological insulators are not suitable as interconnects as they have high resistivity values. The comparison in FIG. 36 demonstrates that MoP is a superior material for interconnect applications. It remains to be seen if another topological semimetal may outperform MoP at small dimensions due to more prominent contributions from their topological surface states.

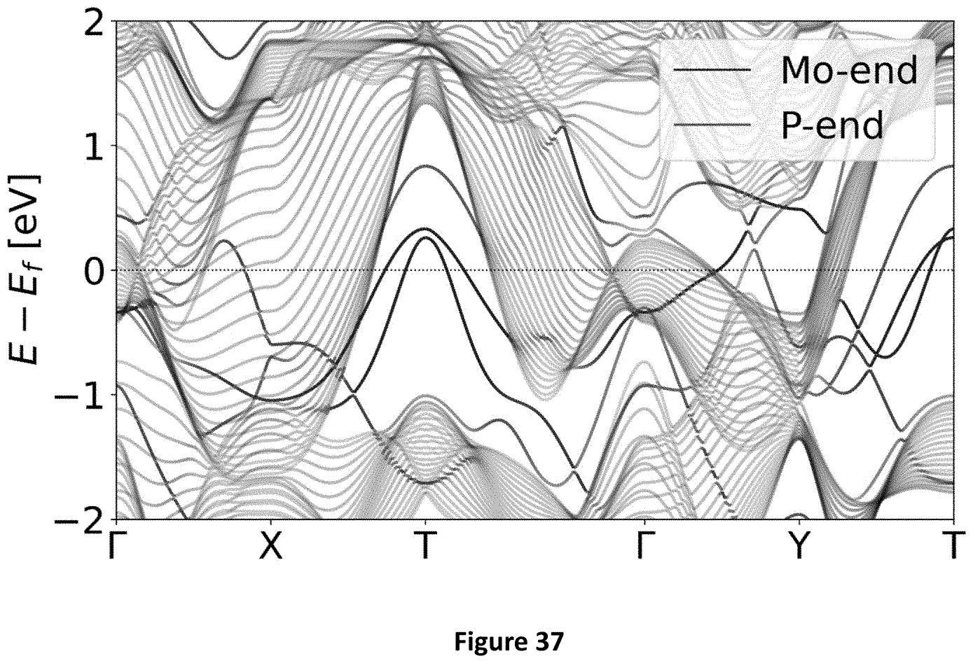

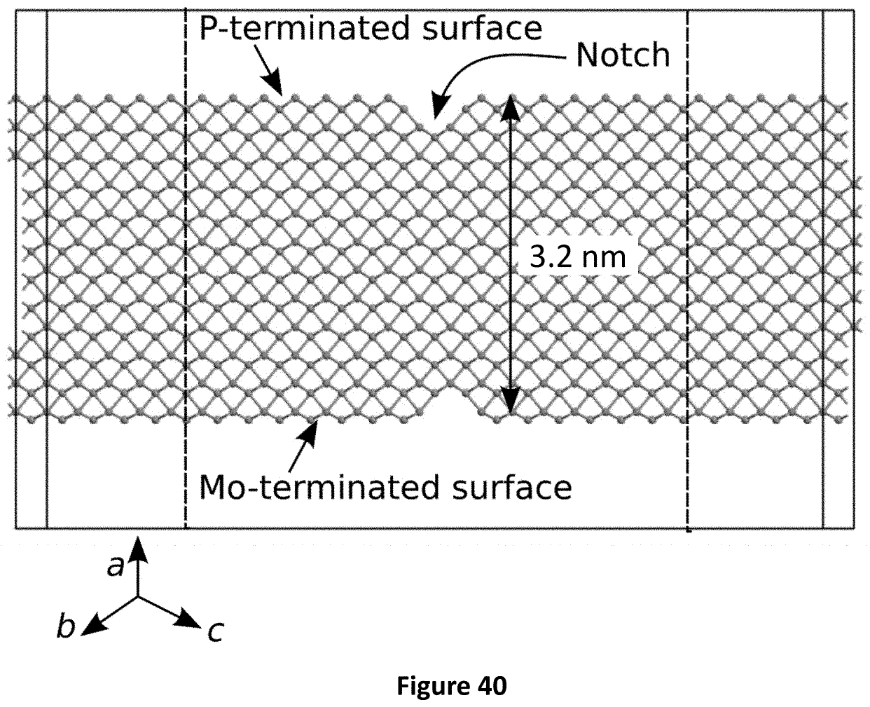

The room temperature transport data of MoP nanowires do not suggest any obvious effects from the topological surface states or suppression of electron backscattering (see FIGS. 37-41 for additional calculations of MoP thin slabs and discussions on the lack of topological effects). Regardless, the resistivity values of the MoP nanowires are already lower than those of Cu interconnects below 500 nm² cross-section areas, and the resistivity scaling behavior of MoP nanowires is superior to those of Cu and Ru interconnects. Thus, this work demonstrates MoP as a breakthrough material for interconnect technologies for continued downscaling of integrated circuits and future energy-efficient computing.

The Materials and Methods will now be Described

Synthesis of MoP nanowires: MoO₃ nanowires were used as the precursor to synthesize MoP nanowires. MoO₃ nanowires were grown by CVD, as previously reported (H. J. Han, et al. APL Mater. 8, 011103 (2020)). 0.15 g of the MoO₃ source powder (Sigma-Aldrich, 99.95%) was placed at the center of a 1 in. tube furnace with anodized aluminum oxide (AAO, InRedox) substrates located 14 cm downstream. After purging with Ar, the system was pumped down to 200 mTorr, and then H₂ was flowed at 20 sccm, bringing the furnace pressure to 5 Torr The furnace was heated to 600° C. in 15 min and held at that temperature for 10 min to produce MoO₃ nanowires with high yield.

MoP nanowires were synthesized by converting MoO₃ nanowires. MoO₃ nanowires were placed in a tube furnace with a sufficient amount (3 g) of NaH₂PO₂.H₂O (Sigma-Aldrich, ≥99%) placed upstream (15-17 cm from the center of the furnace). After purging with Ar, the system was pumped down to 200 m Torr, and then H₂ was flowed at 20 sccm, bringing the furnace pressure to atmospheric pressure. The furnace was heated to 700° C. in 30 min, held there for 1 hr, and then cooled down to room temperature naturally.

Characterization of MoP nanowires: Structural characterization of the MoP nanowires was carried out using SEM and TEM. A field emission SEM (Hitachi S-4800) was used at an acceleration voltage of 10 kV and a working distance of 5 mm. High-resolution TEM images were obtained using a 200 kV accelerating voltage TEM (FEI, Talos F200X). Atomic-resolution STEM images were obtained using a probe-corrected microscope (ThermoFisher Scientific, Spectra 300) at 200 kV. Raman spectra were obtained using a Horiba LabRAM HR Evolution Spectrometer with an excitation wavelength of 532 nm. For chemical compositions of the nanowires, X-ray photoelectron spectroscopy (XPS) data were acquired using a multipurpose X-ray photoelectron spectrometer (Sigma Probe; Thermo VG Scientific). The X-ray diffraction (XRD) measurements were carried out using a multipurpose thin-film X-ray diffractometer (D/Max 2500; Rigaku).

Device fabrication and transport measurements: Synthesized MoP nanowires were transferred onto SiO₂/Si substrates by stamping and coated with triple e-beam resist layers (˜200 nm PMMA A3 as the first layer, ˜200 nm MMA EL 8.5 as the second layer, and ˜200nm PMMA A3 as the third layer). Electrode patterns were obtained by standard e-beam lithography using a Vistec EBPG 5000+. The devices were designed for four-probe measurements, and the distance between the electrodes was kept at ˜200 nm. After the pattern was developed, 10/100 nm-thick Cr/Au electrical contacts were deposited by e-beam evaporation. Transport measurements at low temperature were performed using a Quantum Design Dynacool physical property measurement system equipped with a base temperature of 2 K. Transport data were taken at applied currents ranging between 10 μA and 100 μA.

CVD growth of 2D MoP single crystal nanoplates for thermal conductivity measurements: A liquid droplet of gallium (Ga, Sigma-Aldrich, 99.9995%) was placed onto 1 cm×1cm molybdenum (Mo) foil (Sigma-Aldrich, 99.9%) substrate. The Ga—Mo substrate was then heated in a quartz tube to 1100° C. at a heating rate of 30° C. min⁻¹. At 1100° C., red phosphorus powder (Sigma-Aldrich, ≥99.99%) was introduced into the tube furnace downstream where the temperature was around 400° C. The furnace was kept at 1100° C. for 20 min under the flow of Ar (250 sccm) and H₂ (50 sccm).

Theoretical calculations: Open-source planewave Density Functional Theory (DFT) code JDFTx (R. Sundararaman, et al. SoftwareX. 6, 278-284 (2017)) was used to compute the bulk resistivity and resistivity scaling of MoP and Cu. The electronic structure of MoP was calculated using the fully relativistic revised Perdew-Burke-Ernzerhof (PBEsol) (J. P. Perdew, et al. Phys. Rev. Lett. 100, 1-4 (2008)) pseudopotentials and generalized gradient approximation (GGA) exchange-correlational functional. A planewave cut-off of 35 Hartrees and a Fermi smearing of 0.01 Hartrees was used. A k-mesh of 12×12×12 and a q-mesh of 3×3×3 were employed for the electron and phonon calculations respectively. Subsequently, the electronic states, phonon modes, and electron-phonon matrix elements are transformed to the maximally localized Wannier function basis (N. Marzari, et al. Phys. Rev. B-Condens. Matter Mater. Phys. 56, 12847-12865 (1997)) and interpolated to a very fine mesh (˜10⁵ points) to obtain converged integrals for the linearized Boltzmann solution for bulk resistivity. The electron-phonon lifetimes are computed using the Fermi's golden rule. For details of the implementation of these methods, refer to (A. Habib, et al. J. Opt. (United Kingdom). 20 (2018), doi:10.1088/2040-8986/aac1d8) and (S. Kumar, et al. arXiv Prepr., in press, available at http://arxiv.org/abs/2205.05007). The resistivity scaling for single-crystalline square wires was calculated using an asymptotic expansion of the Boltzmann solution as detailed in S. Kumar, et al. (arXiv Prepr., in press, available at http://arxiv.org/abs/2204.13458). Additional calculations for thin slabs of MoP are shown in FIGS. 37-41.

Thermal conductivity measurements: The thermal conductivities of MoP nanoplates and a bulk crystal were determined by TDTR measurements. An Al layer (˜80-100 nm) was coated on the surface of the MoP sample as the transducer layer. A mode-locked Ti: Sapphire laser with a wavelength of ˜785 nm was split into the pump beam and the probe beam by optical filters. The pump beam was modulated by an electro-optical modulator with a frequency of 9.3 MHz, generating a temperature rise on the sample surface. The probe beam was modulated with a frequency of 200 Hz and to detect the temperature change on the sample surface after a delay time. The pump and probe beam were focused on the sample surface by an objective lens (20× for MoP nanoplates and 10× for MoP bulk). The reflectance of the probe beam was picked up at the frequency of the pump beam by an RF lock-in amplifier, then two computer-based lock-ins detected the RF lock-in outputs at the frequency of the probe beam. The ratio signals (−Vᵢₙ/Vₒᵤₜ, Vᵢₙ: in-phase voltage signal, Vₒᵤₜ: out-of-phase voltage signal) were collected and then fit to an analytical solution of a heat transfer equation for a multilayer model of the sample structure.

In data analysis, the structure of MoP nanoplates was Al/MoP/SiO₂/Si, and the thermal conductance of the Al/MoP interface and the thermal conductivity of MoP were fit as unknown parameters. The thermal conductivity of Al was 166 W/m-K, measured by a four-point method and calculated from the Wiedemann-Franz law. The volumetric heat capacities of Al and MoP were from previous literatures, which are 2.43 and 2.50 J/cm³-K, respectively (D. A. Ditmars, et al. Int. J. Thermophys. 6, 499-515 (1985)). The thermal conductance of the MoP/SiO₂ interface was set to be 10 MW/m²-K, although the MoP nanoplate was thermally thick and the TDTR measurements were not sensitive to the segments below MoP. As for the MoP bulk sample, the structure was Al/MoP, and the thermal conductivity of Al was 162 W/m-K.

Modeling of electrical resistivity as function of wire size: FIG. 28 shows the electrical resistivity of polycrystalline square wires of MoP and Cu as a function of wire width plotted using the Fuchs-Sondhemier and Mayadas-Shatzkes equation:

$$ρ = {ρ}_{0} + \frac{{ρ}_{0} λ}{d} \frac{3 ( 1 - p )}{4} + \frac{{ρ}_{0} λ}{2 D} \frac{3 R}{( 1 - R )} .$$

Here, ρ0 is the bulk resistivity of the metal, λ is the electron mean free path, d is the width of the square wire, D is the grain size, p is the surface specularity and R is the reflectivity of the grains. The average grain size D˜d for both Cu and MoP has been assumed. Two curves corresponding to the cases of zero (solid line) and 3-nm thick liner (dashed line) have been plotted for Cu. Additionally, a reflectivity of 0.4 and completely diffuse scattering (p=0) have been assumed. For MoP, the experimentally measured ρ0 is used and the the values of R and p were extracted by fitting the experimental data near ˜20 nm. One can have several combinations of p and R to fit the curve using the above equation. For example, the following combinations would yield the same curve for MoP: (1)p=0, R=0.13,(2)p=0.5,R=0.29 and (3)p=1,R=0.4. MoP, when used without liner, can easily outperform Cu with liner at smaller dimensions.

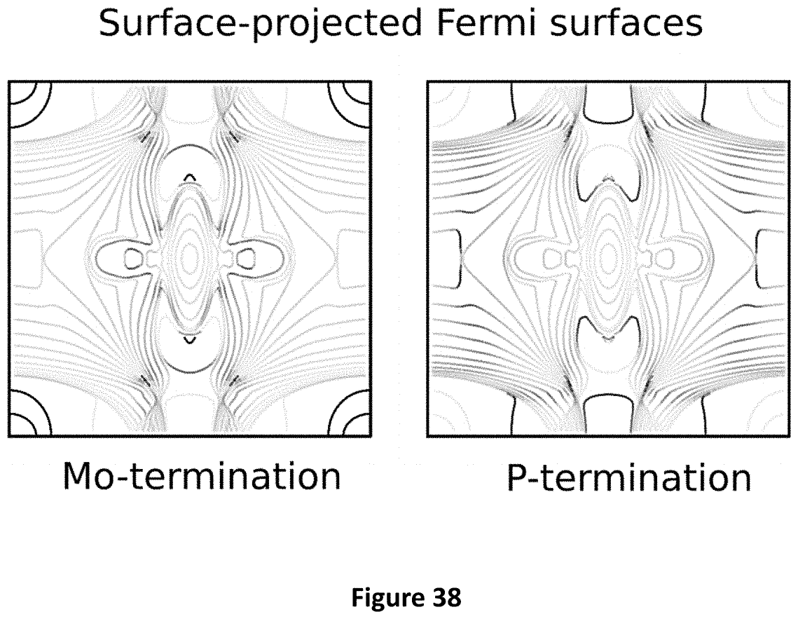

First-principles study of ballistic electron transport in MoP films: First-principles calculations were used to examine the transport properties of MoP as a function of film thickness. FIG. 37 shows the electronic bandstructure of a 24 atomic layer (1000) slab of MoP (˜6.5 nm thick), with the color indicating the weight of each state on a surface relative to bulk. A large number of bulk states (gray) cross the Fermi level, compared to few surface states (red and blue). This can be seen in FIG. 38 as well, which plots the individual surface-projected Fermi surfaces for the Mo-terminated (blue) and P-terminated (red) surfaces. Here again, almost all the electronic states that form the Fermi surface come from the bulk of the slab.

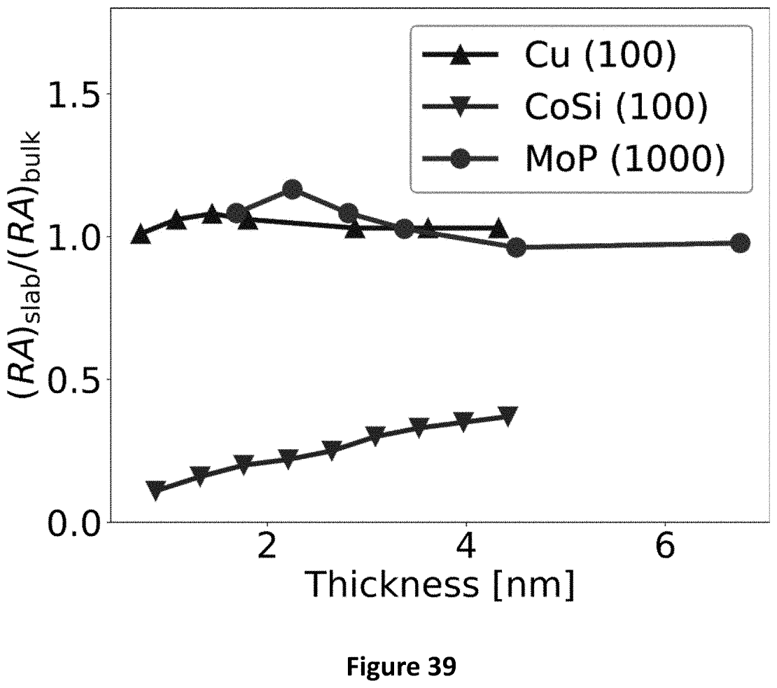

While the above analysis gives us an insight into the relative contributions of the surface and the bulk to the electronic states at the Fermi level, ab initio calculations are performed to examine the ballistic transport properties. FIG. 39 shows the normalized resistance-area (RA) product of pristine MoP (1000) films as a function of slab thickness. For comparison, the normalized RA product for pristine films of Cu and the topological semimetal CoSi as calculated by Chen et al. are plotted (C.-T. Chen, et al., in 2020 IEEE International Electron Devices Meeting (IEDM) (IEEE, 2020; https://ieeexplore.ieee.org/document/9371996/), vols. 2020-December, pp. 32.4.1-32.4.4). RA product scaling for MoP is very similar to that of Cu wherein the values of (RA)_{slab} are almost the same as that of (RA)_{bulk} and remains constant with thickness. This is in stark contrast to the conductance scaling of CoSi where the transport is dominated by topologically-protected Fermi-arc surface states which results in decreasing (RA)_{slab} with decreasing thickness. However, the abundance of bulk states at the Fermi level for MoP indicates that the current is carried mostly by the bulk.

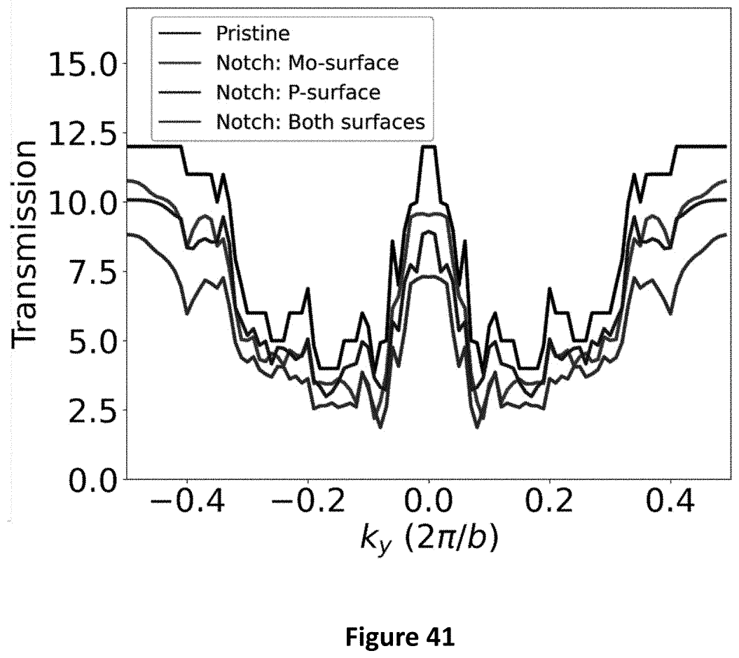

Chen et al. showed that for CoSi the Fermi-arc states are robust against surface defects and topological protection prevents the backscattering of surface states. Non-Equilibrium Green's Function (NEGF) calculations were performed to study how similar defects affect ballistic transport in MoP slabs using QuantumATK (S. Smidstrup, et al., J. Phys. Condens. Matter. 32 (2020), doi:10.1088/1361-648X/ab4007). The k-resolved transmission for different defect configurations was calculated by removing 3 atoms from each of the surfaces of a ˜3.2 nm thick (1000) slab of MoP. FIG. 41 shows that the introduction of surface defects reduces the transmission of electronic states throughout the Brillouin zone. This contrasts with CoSi where the transmission of Fermi-arc states was found to remain unaffected by surface defects. The ab initio calculations, hence, find no evidence of topologically protected surface transport in MoP films.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

We claim:

1. An integrated circuit comprising a first circuit element operably connected to a second circuit element by a nanowire interconnect; wherein the nanowire interconnect comprises molybdenum phosphide (MoP), tungsten phosphide (WP₂), or niobium phosphide (NbP).

2. The integrated circuit of claim 1, wherein the nanowire interconnect comprises MoP.

3. The integrated circuit of claim 1, wherein the nanowire interconnect is polycrystalline and non-porous.

4. The integrated circuit of claim 1, wherein the nanowire interconnect does not include a liner.

5. The integrated circuit of claim 1, wherein the nanowire interconnect comprises fewer than 30 grain boundaries per micrometer length.

6. The integrated circuit of claim 1, wherein the nanowire interconnect has an average crystal grain size of 20 to 50 nm.

7. The integrated circuit of claim 1, wherein the nanowire interconnect has a diameter less than 100 nm.

8. The integrated circuit of claim 1, wherein the nanowire interconnect has a diameter less than 50 nm.

9. The integrated circuit of claim 1, wherein the nanowire interconnect has a diameter less than 20 nm.

10. The integrated circuit of claim 1, wherein the nanowire interconnect has a resistivity of 30 μΩ·cm to 10 μΩ·cm at room temperature.

11. The integrated circuit of claim 1, wherein the nanowire interconnect is a MoP nanowire and has a resistivity less than or equal to 10 μΩ·cm at room temperature.

12. The integrated circuit of claim 1, wherein the resistivity of the nanowire interconnect does not increase upon exposure to ambient conditions for 48 hours.

13. A microchip comprising the integrated circuit of claim 1.

14. A method of making a topological semimetal nanowire comprising the steps of:
providing a template nanowire;
providing a phosphine source;
producing phosphine from the phosphine source; and
contacting the template nanowire with the phosphine.

15. The method of claim 14, wherein the template nanowire comprises molybdenum oxide, tungsten oxide, or niobium oxide.

16. The method of claim 14, wherein the template nanowire comprises MoO₃.

17. The method of claim 14, wherein the template nanowire has a diameter of less than 50 nm.

18. The method of claim 14, wherein the template nanowire has a diameter of about 10 nm.

19. The method of claim 14, wherein the phosphine source comprises red phosphorous or a hypophosphite salt selected from the group consisting of sodium hypophosphite, potassium hypophosphite, lithium hypophosphite, rubidium hypophosphite, cesium hypophosphite, ammonium hypophosphite and mixtures and solvates thereof.

20. The method of claim 14, wherein the step of producing phosphine from the phosphine source comprises the steps of heating the phosphine source to a temperature greater than 300° C.; and contacting the phosphine source with hydrogen gas.
